(19) United States
(12) Patent Application Publication
(10) Pub. No.: US 2012/0003831 A1
(43) Pub. Date: Jan. 5, 2012

(54) Methods of Forming Nonvolatile Memory Devices Using Nonselective and Selective Etching Techniques to Define Vertically Stacked Word Lines

(76) Inventors: Daehyuk Kang, Hwaseong-si (KR); Sang Won Bae, Namdong-gu (KR); Boun Yoon, Seoul (KR); Kuntach Lee, Suwon-si (KR); Young-Hoo Kim, Hwaseong-si (KR)

(21) Appl. No.: 13/173,591

(22) Filed: Jun. 30, 2011

(30) Foreign Application Priority Data
Jul. 5, 2010 (KR) 10-2010-0064410

(51) Int. Cl. H01L 21/8239

(52) U.S. Cl. 438/639; 257/E21.645

(57) ABSTRACT

Methods of forming nonvolatile memory devices include forming a stack of layers of different materials on a substrate. This stack includes a plurality of first layers of a first material and a plurality of second layers of a second material arranged in an alternating sequence of first and second layers. A selected first portion of the stack of layers is isotropically etched for a sufficient duration to define a first trench therein that exposes sidewalls of the alternating sequence of first and second layers. The sidewalls of each of the plurality of first layers are selectively etched relative to sidewalls of adjacent ones of the plurality of second layers. Another etching step is then performed to recess sidewalls of the plurality of second layers and thereby expose portions of upper surfaces of the plurality of first layers. These exposed portions of the upper surfaces of the plurality of first layers, which may act as word lines of a memory device, are displaced laterally relative to each other.

### REFERENCE TO PRIORITY APPLICATION

This U.S. non-provisional patent application claims priority under 35 U.S.C. §119 of Korean Patent Application No. 10-2010-0064410, filed on Jul. 5, 2010, the entire contents of which are hereby incorporated by reference.

### BACKGROUND

The present disclosure relates to semiconductor devices and methods of forming same and, more particularly, to three-dimensional semiconductor devices and methods of forming same.

The increasing degree of integration in semiconductor devices is on demand to satisfy excellent performance and reasonable price. Especially, the degree of integration in a semiconductor memory device is an important factor for determining a product's price. The integration degree of a typical two-dimensional semiconductor memory device is mainly determined by an area that a unit memory cell occupies, so that it is greatly affected by a level of a fine pattern formation technique. However, since high-priced equipment is required for miniaturizing a pattern, although the integration degree of a two-dimensional semiconductor memory device is increased, it is still limited.

In order to overcome these limitations, three-dimensional semiconductor memory devices including three-dimensionally arranged memory cells are suggested. However, to achieve mass production of three-dimensional semiconductor memory devices, process technologies for reducing manufacturing costs per bit more than compared to second-dimensional semiconductor memory devices and realizing reliable product characteristics are required.

### SUMMARY OF THE INVENTION

Methods of forming a nonvolatile memory device include forming a stack of layers of different materials on a substrate. This stack includes a plurality of first layers of a first material and a plurality of second layers of a second material arranged in an alternating sequence of first and second layers. A selected first portion of the stack of layers is isotropically etched for a sufficient duration to define a first trench therein that exposes sidewalls of the alternating sequence of first and second layers. The sidewalls of each of the plurality of first layers are then selectively etched relative to sidewalls of adjacent ones of the plurality of second layers. Thereafter, another etching step is performed to recess sidewalls of the plurality of second layers and thereby expose portions of upper surfaces of the plurality of first layers. These exposed portions of the upper surfaces of the plurality of first layers are displaced laterally relative to each other.

According to some embodiments of the invention, the plurality of first layers include an electrically conductive material and the plurality of second layers include an electrically insulating material. For example, the plurality of first layers may include polycrystalline silicon. The recessing of the sidewalls of the plurality of second layers may also be followed by selectively etching the plurality of first layers in sequence to define a plurality of side-by-side stacks of word lines of the memory device. Vertically-extending conductive pillars may also be formed on the exposed portions of the upper surfaces of the plurality of first layers.

According to still further embodiments of the invention, methods of forming nonvolatile memory devices may include forming a stack of layers of different materials on a substrate. This stack of layers includes a plurality of first layers of a first material and a plurality of second layers of a second material, which are arranged in an alternating sequence of first and second layers. A selected (e.g., photolithographically defined) first portion of the stack of layers is isotropically etched for a sufficient duration to define a first trench therein that exposes sidewalls of the alternating sequence of first and second layers. The sidewalls of each of the plurality of first layers exposed by the trench are then recessed relative to sidewalls of adjacent ones of the plurality of second layers by selectively etching the first material at a faster rate than the second material. Thereafter, the first portion of the stack of layers is again isotropically etched for a sufficient duration to deepen the first trench. The sidewalls of the plurality of second layers are then recessed relative to sidewalls of the plurality of first layers to thereby expose portions of upper surfaces of the plurality of first layers. In some of these embodiments of the invention, the step of isotropically etching the first portion of the stack of layers for a sufficient duration to deepen the first trench includes isotropically etching the first portion of the stack of layers for a sufficient duration to expose the substrate.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a block diagram illustrating a three-dimensional semiconductor device according to embodiments of the inventive concept;

FIG. 2 is a block diagram illustrating an example of the memory cell array of FIG. 1;

FIG. 3 is a circuit diagram of the memory block described with reference to FIGS. 1 and 2;

FIG. 4A is a view illustrating a portion of a layout of a three-dimensional semiconductor device according to an embodiment of the inventive concept.

FIG. 4B is a sectional view taken along the line I-I′ of FIG. 4A.

FIG. 4C is a perspective view illustrating a first region of FIG. 4A.

FIG. 4D is an enlarged view of A of FIG. 4B;

FIG. 5A is a portion of a layout of a three-dimensional semiconductor device according to another embodiment of the inventive concept.

FIG. 5B is a sectional view taken along the line II-II′ of FIG. 5A.

FIG. 5C is a perspective view of a first region R1 of FIG. 5A;

FIG. 6A is a portion of a layout of a three-dimensional semiconductor device according to another embodiment of the inventive concept.

FIG. 6B is a sectional view taken along the line II-II′ of FIG. 6A.

FIG. 6C is a perspective view of a first region R1 of FIG. 6A;

FIGS. 7A through 7H illustrate a method of forming the three-dimensional device described with reference to FIGS. 4A through 4D and are sectional views corresponding to the line I-I′ of FIG. 4A;

FIGS. 8A through 8H illustrate a method of forming the three-dimensional semiconductor device described with reference to FIGS. 5A through 5C and are sectional views taken along the line II-II′ of FIG. 5A;

FIGS. 9A through 9D illustrate a method of forming the three-dimensional semiconductor device described with reference to FIGS. 6A through 6C and are sectional views taken along the line of FIG. 6A;

FIGS. 10 through 13 illustrate a method of forming a three-dimensional semiconductor device according to an embodiment of the inventive concept and are sectional views corresponding to the region B of FIGS. 7C, 8C, and 9C;

FIGS. 14 through 17 illustrate a method of forming a three-dimensional semiconductor device according to another embodiment of the inventive concept and are sectional views corresponding to the region B of FIGS. 7C, 8C, and 9C;

FIGS. 18 through 22 illustrate a method of forming a three-dimensional semiconductor device according to a further another embodiment of the inventive concept and are sectional views corresponding to the region B of FIGS. 7C, 8C, and 9C;

FIGS. 23 through 29 illustrate a method of forming a three-dimensional semiconductor device according to a further another embodiment of the inventive concept and are sectional views corresponding to the region B of FIGS. 7C, 8C, and 9C;

FIG. 30 is a perspective view illustrating a stacked pattern of a stepped shape formed with reference to FIGS. 10 through 29;

FIG. 31 is a sectional view illustrating stepped structure of the three-dimensional semiconductor device of the inventive concept described with reference to FIG. 4B, which is formed through the method of FIG. 29;

FIGS. 33A, 33B, and 33C are enlarged sectional views of portions S, S′, and S″ of FIG. 31;

FIG. 33 is enlarged section views of portions C and C′ of FIG. 31;

FIG. 34 is a circuit diagram illustrating one modification of the memory block described with reference to FIGS. 1 and 2;

FIG. 35 is a circuit diagram illustrating one modification of the memory block described with reference to FIGS. 1 and 2;

FIG. 36 is a circuit diagram illustrating one modification of the memory block described with reference to FIGS. 1 and 2;

FIG. 37 is a circuit diagram illustrating one modification of the memory block described with reference to FIGS. 1 and 2;

FIG. 38 is a circuit diagram illustrating one modification of the memory block described with reference to FIGS. 1 and 2;

FIG. 39 is a circuit diagram illustrating one modification of the memory block described with reference to FIGS. 1 and 2;

FIG. 40 is a circuit diagram illustrating one modification of the memory block described with reference to FIGS. 1 and 2;

FIG. 41 is a block diagram illustrating a memory system including the above-mentioned three-dimensional semiconductor device;

FIG. 42 is a block diagram illustrating an application example of the memory system of FIG. 41; and

FIG. 43 is a block diagram illustrating a computing system including the memory system described with reference to FIG. 42.

### DETAILED DESCRIPTION OF THE EMBODIMENTS

Exemplary embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. In the drawings, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout. Hereinafter, exemplary embodiments of the inventive concept will be described in detail with reference to the accompanying drawings. In embodiments below, a wet etching process will be described as an example of an isotropic etching process. However, according to the inventive concept, the isotropic etching process is not limited to a wet etching process and thus may include an isotropic etching process using plasma.

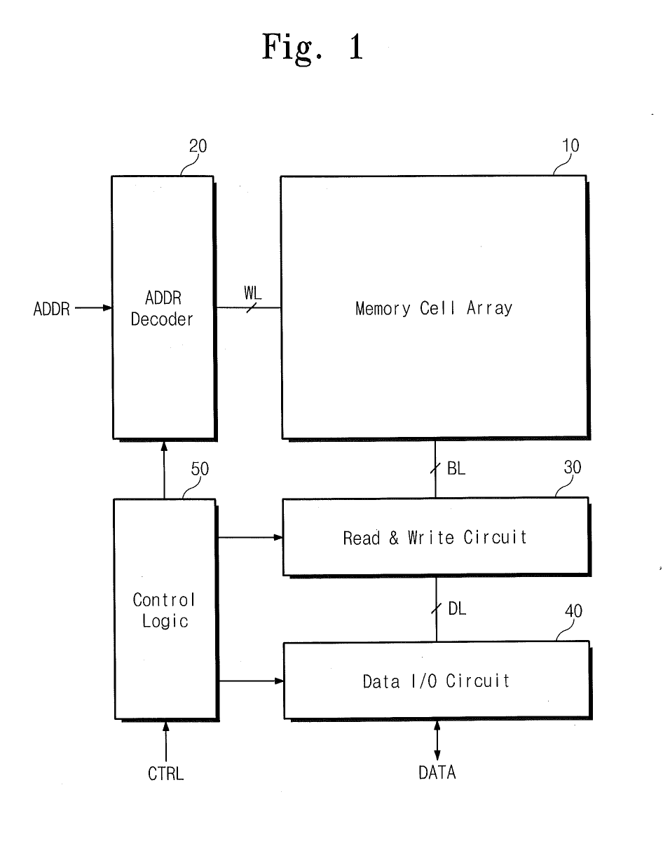

Referring to FIG. 1, the three-dimensional semiconductor device according to embodiments of the inventive concept may include a memory cell array 10, an address decoder 20, a read and write circuit 30, a data input/output (I/O) circuit 40, and a control logic 50. The memory cell array 10 may be connected to the address decoder 20 through a plurality of word lines WL and may be connected to the read and write circuit 30 through bit lines BL. The memory cell array 10 includes a plurality of memory cells. For example, the memory cell array 10 may be configured to store one or more than one bit per cell. The address decoder 20 may be connected to the memory cell array 10 through the word lines WL. The address decoder 20 is configured to operate in response to a control of the control logic 50. The address decoder 20 may receive addresses ADDR from an external device. The address decoder 20 decodes a row address among the received addresses ADDR to select a corresponding word line among the plurality of word lines WL. Additionally, the address decoder 20 decodes a column address among the received addresses ADDR and delivers the decoded column address to the read and write circuit 30. For example, the address decoder 20 may include well-known typical components such as a row decoder, a column decoder, and an address buffer.

The read and write circuit 30 may be connected to the memory cell array 10 through the bit lines BL and may be connected to the data I/O circuit 40 through data lines DL. The read and write circuit 30 may operate in response to a control of the control logic 50. The read and write circuit 30 is configured to receive a column address decoded from the address decoder 20. Using the decoded column address, the read and write circuit 30 selects the bit lines BL. For example, the read and write circuit 30 receives data from the data I/O circuit 40 and writes the received data on the memory cell array 10. The read and write circuit 30 reads data from the memory cell array 10 and delivers the read data to the data I/O circuit 40. The read and write circuit 30 reads data from a first storage region of the memory cell array 10 and writes the read data on a second storage region of the memory cell array 10. For example, the read and write circuit 30 may be configured to perform a copy-back operation.

The read and write circuit 30 may include components such as a page buffer (or a page register) and a column selection circuit. As another example, the read and write circuit 30 may include components such as a sense amplifier, a write driver, and a column selection circuit. The data I/O circuit 40 may be connected to the read and write circuit 30 through the data lines DL. The data I/O circuit 40 may operate in response to a control of the control logic 50. The data I/O circuit 40 is configured to exchange data DATA with the external device. The data I/O circuit 40 is configured to deliver the delivered data DATA from external to the read and write circuit 30 through the data lines DL. The data I/O circuit 40 is configured to output the data DATA, delivered from the read and write circuit 30 through the data lines DL, to the external. For example, the data I/O circuit 40 may include a component such as a data buffer. The control logic 50 may be connected to the address decoder 20, the read and write circuit 30, and the data I/O circuit 40. The control logic 50 may be configured to control operations of the three-dimensional semiconductor device. The control logic 50 may operate in response to a control signal CTRL delivered from the external.

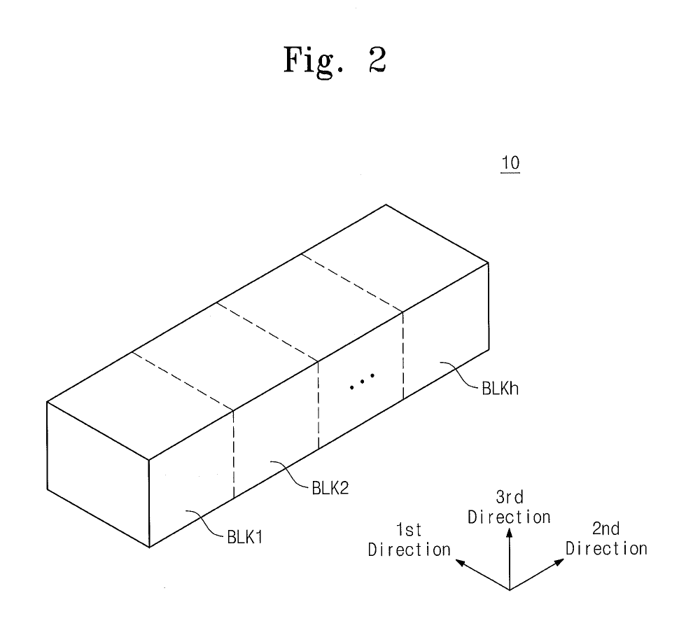

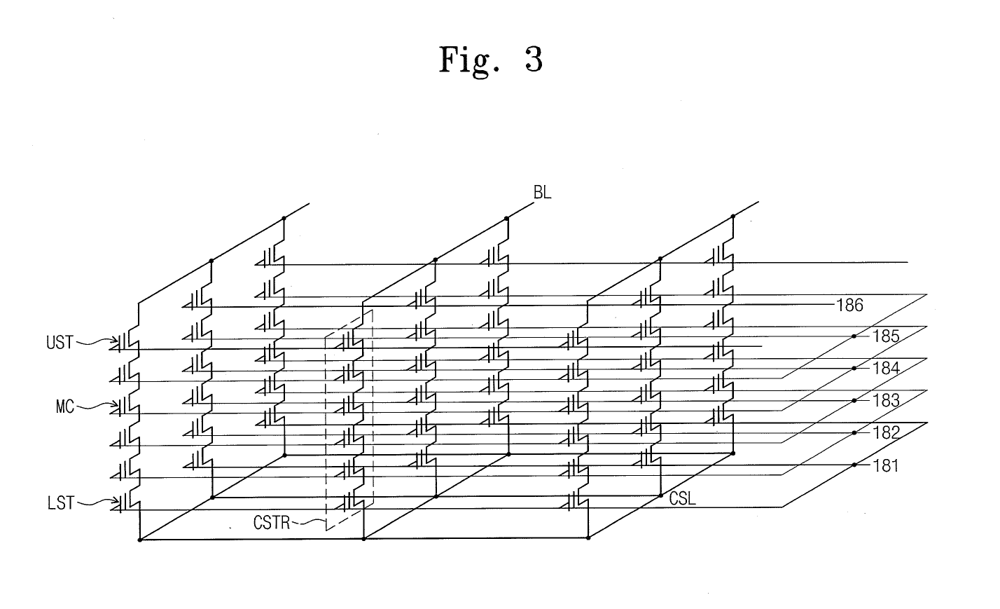

FIG. 2 is a block diagram illustrating an example of the memory cell array 10 of FIG. 1. Referring to FIG. 2, the memory cell array 10 may include a plurality of memory blocks BLK1 to BLKh. Each memory block may have a three-dimensional structure (or a vertical structure). For example, each memory block may include structures extending in first to third directions intersecting each other. For example, each memory block includes a plurality of cell strings CSTR extending in the first direction. For example, the plurality of cell strings CSTR may be provided along the first and second directions. FIG. 3 is a circuit diagram of the memory block described with reference to FIGS. 1 and 2. Referring to FIG. 3, a three-dimensional semiconductor device according to embodiments of the inventive concept may include bit lines BL, word lines WL0 to WL3, an upper selection line USL, a lower selection line LSL, and a common source line CSL. The plurality of cell strings CSTR are provided between the bit lines BL and the common source line CSL.

The cell strings CSTR may include an upper selection transistor UST connecting to the bit liens BL, a lower selection transistor LST connecting to the common source line CSL, and a plurality of memory cells MC provided between the upper selection transistor UST and the lower selection transistor LST. A drain of the upper selection transistor UST is connected to the bit lines BL and a source of the lower selection transistor LST is connected to the common source line CSL. A gate of the upper selection transistor UST is connected to the upper selection line USL, and a gate of the lower selection transistor LST is connected to the lower selection line LSL. Gates of the memory cells MC are connected to the word lines WL0 to WL3.

The cell strings CSTR may have a structure where the memory cells MC are connected in series in a direction (i.e., the third direction) vertical to the surface of the substrate. Accordingly, the selection transistors UST and LST and channels of the memory cells MC may be provided in the third direction. A three-dimensional semiconductor device according to the inventive concept may be a NAND flash memory device having cell strings CSTR. At this point, the lower selection line LSL is a ground selection line of the NAND flash memory device and the upper selection line USL may be a string selection line of the NAND flash memory device.

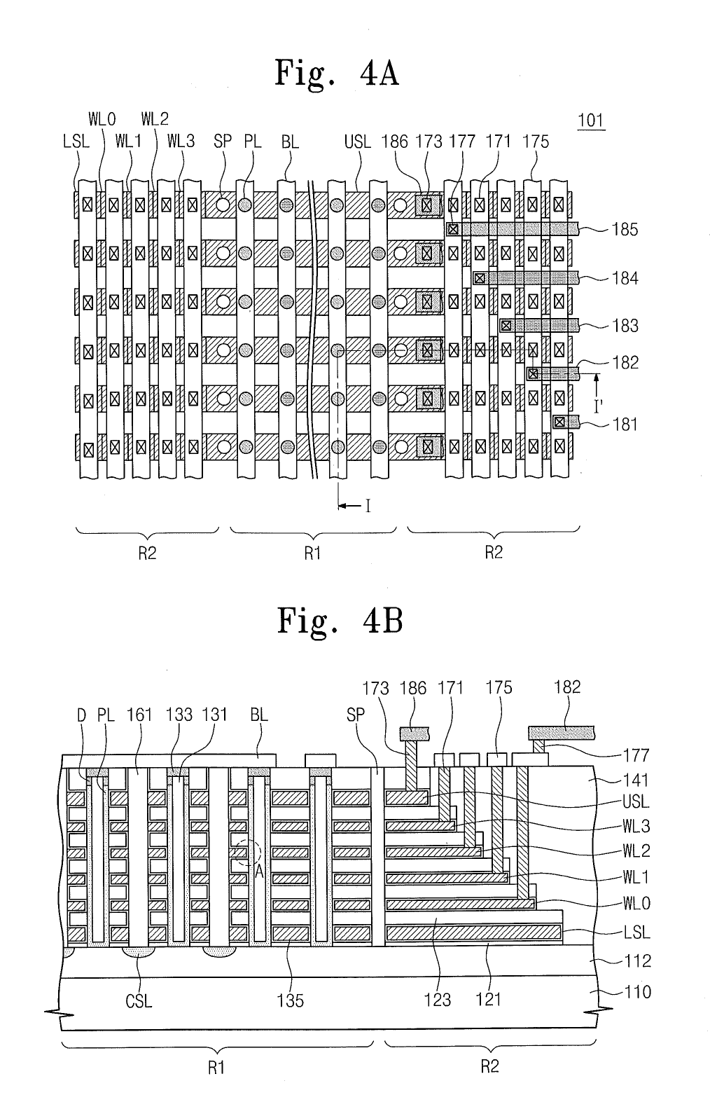

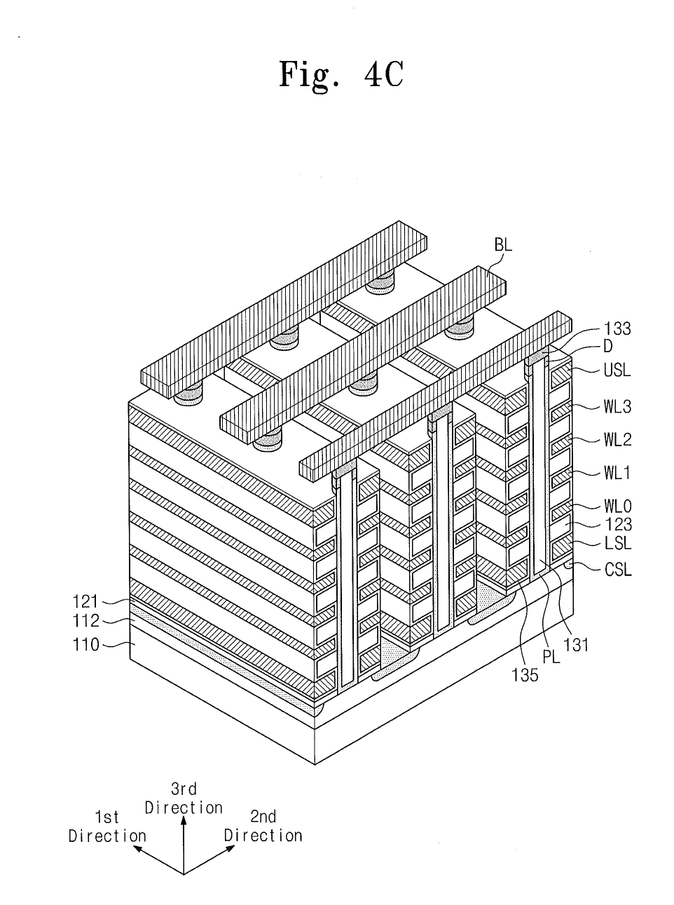

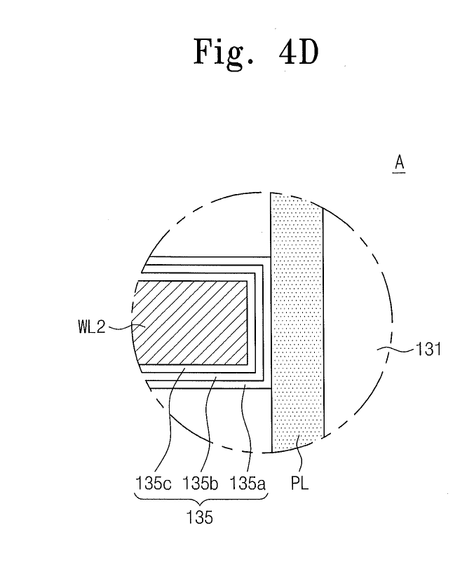

FIG. 4A is a view illustrating a portion of a layout of a three-dimensional semiconductor device 101 according to an embodiment of the inventive concept. FIG. 4B is a sectional view taken along the line I-I′ of FIG. 4A. FIG. 4C is a perspective view illustrating a first region of FIG. 4A. FIG. 4D is an enlarged view of A of FIG. 4B. Referring to FIGS. 4A through 4D, the three-dimensional semiconductor device 101 is described. A buffer dielectric layer 121 may be provided on a substrate 110. A first conductive type well 112 may be provided on the substrate 110. The buffer dielectric layer 121 may be a silicon oxide layer. Insulation patterns 123 and conductive patterns LSL, WL0 to WL3, and USL spaced from each other with the interposed insulation patterns 123 may be provided on the buffer dielectric layer 121.

More specifically, the substrate 110 includes a first region R1 and a second region R2 disposed at the edge portion of the first region R1. The second region R2 may be provided to the circumference of the first region R1. In FIG. 4A, it is shown that the second region R2 are provided at the both side portions of the first region R1. In one embodiment, the first region R1 is a memory cell region and the second region R2 may be a connection region used for connecting the word liens of the memory cell region with an external circuit. The conductive patterns LSL, WL0 to WL3, and USL may include a lower selection line LSL, an upper selection line USL, and word lines WL0 to WL3 therebetween. The conductive patterns may have a line shape extending in a first direction parallel to the substrate. The first region R1 may correspond to the center of the line-shaped conductive patterns and the second region R2 may correspond to an end portion(s) at one side or both sides of the line-shaped conductive patterns. The conductive patterns may include at least one of doped silicon, tungsten, metal nitride layers, and metal silicides.

A plurality of active pillars PL penetrating the conductive patterns LSL, WL0 to WL3, and USL to connect to the substrate 110 are provided in the first region R1. The active pillars PL may have a major axis (i.e., extending in the third direction) extending from the substrate 110 to the top. The active pillars PL may include a semiconductor material. The active pillars PL may have a filled cylindrical shape or an empty cylindrical shape (e.g., a macaroni shape). The inside of the macaroni-shaped active pillars may be filled with an insulation material. In one aspect of the inventive concept, the active pillars PL and the substrate 110 may be a semiconductor of a continuous structure. The active pillars PL may be a single crystalline semiconductor. In another aspect of the inventive concept, the active pillars PL and the substrate 110 may have a discontinuous interface. The active pillars PL may be a semiconductor of a polycrystalline or amorphous structure. The active pillars PL may include a body adjacent to the substrate 110 and an upper drain region D spaced from the top of the substrate. The body may have the first conductive type and the drain region D may have a second conductive type different from the first conductive type.

One ends (i.e., the body) of the active pillars PL may be connected to the substrate 110, other ends (i.e., the drain region) may be connected to the bit lines BL. The bit lines BL may extend in a second direction intersecting the first direction. One active pillar is connected to one bit line so that one bit line may be connected to a plurality of strings CSTR. The active pillars PL may be arranged in a matrix of the first direction and the second direction. Accordingly, intersection points between the word lines WL0 to WL3 and the active pillars PL are three-dimensionally distributed. Memory cells MC of the three-dimensional semiconductor device 101 according to the inventive concept are provided on the three-dimensionally arranged intersection points. As a result, one memory cell is defined by one active pillar and one word line.

An information storage layer 135 may be provided between the word lines WL0 to WL3 and the active pillars PL. The information storage layer 135 may extend on the top surface and the bottom surface of the word lines. The information storage layer 135 may include a blocking insulation layer 135c adjacent to the word liens WL0 to WL3, a tunnel insulation layer 135a adjacent to the active pillars PL, and a charge storage layer 135b therebetween. The blocking insulation layer may include a high dielectric layer (e.g., an aluminum oxide layer or a hafnium oxide layer). The blocking insulation layer 135c may be a multilayer consisting of a plurality of thin layers. For example, the blocking insulation layer 135c may include an aluminum oxide layer and a silicon oxide layer and a stacking order of an aluminum oxide layer and a silicon oxide layer may vary. The charge storage layer 135b may be an insulation layer including a charge trap layer or a conductive nano particle. The charge trap layer may include a silicon nitride layer, for example. The tunnel insulation layer 135a may include a silicon oxide layer.

The three-dimensional semiconductor device 101 may be a NAND flash memory device where memory cells in one active pillar constitute one cell string. Supporters SP penetrating the conductive patterns LSL, WL0 to WL3, and USL are provided in the second region R2. The supporters SP may have a major axis (i.e., extending in the third direction) extending from the substrate 110 to the top. The supporters SP may be a pillar formed of an insulation material. The supporters SP spaced from the active pillars PL may be provided. For example, the supporters SP may be provided at one side of the active pillars PL disposed at the edge of the first region R1.

The conductive patterns LSL, WL0 to WL3, and USL may have a stepped structure in the second region R2. For example, in relation to the conductive patterns, the conductive patterns include an upper conductive pattern and a lower conductive pattern under the upper conductive pattern. The lower conductive pattern protrudes to the side more compared to the upper conductive patterns so that a top surface of the lower conductive pattern may be exposed by the upper conductive pattern. As the conductive patterns LSL, WL0 to WL3, and USL become far from the substrate 110, their areas become reduced and they are stacked. A first interlayer insulation layer 141 covering the stepped conductive patterns is provided. First and second conductive pillars 171 and 173 may be provided to penetrate the insulation patterns 123 and the first interlayer insulation layer 141 such that they may connect to the exposed top surfaces of the conductive patterns, respectively.

The conductive patterns LSL, WL0 to WL3, and USL extending in the first direction may be spaced from each other in the second direction and may be provided in plurality. The plurality of upper selection lines USL may be connected to third conductive lines 186 extending in the first direction through the second conductive pillars 173. The conductive pattern of the same layer in the remaining conductive patterns LSL, and WL0 to WL3 may be connected to the same connection pattern 175 extending in the second direction through the first conductive pillars 171. The connection pattern 175 may be connected to the first conductive line 181 and the second conductive lines 182 to 185 through third conductive pillars 177. In the same manner, the conductive patterns of the same layer may be commonly connected to the first conductive line 181 or one of the second conductive lines 182 to 185. An insulating separation pattern 161 may be provided between the conductive patterns LSL, WL0 to WL3, and USL adjacent to the second direction. The separation pattern 161 may be a silicon oxide layer. A common source line CSL is provided in the well 112 below the separation patter 161. The common source line CSL may have the second conductive type.

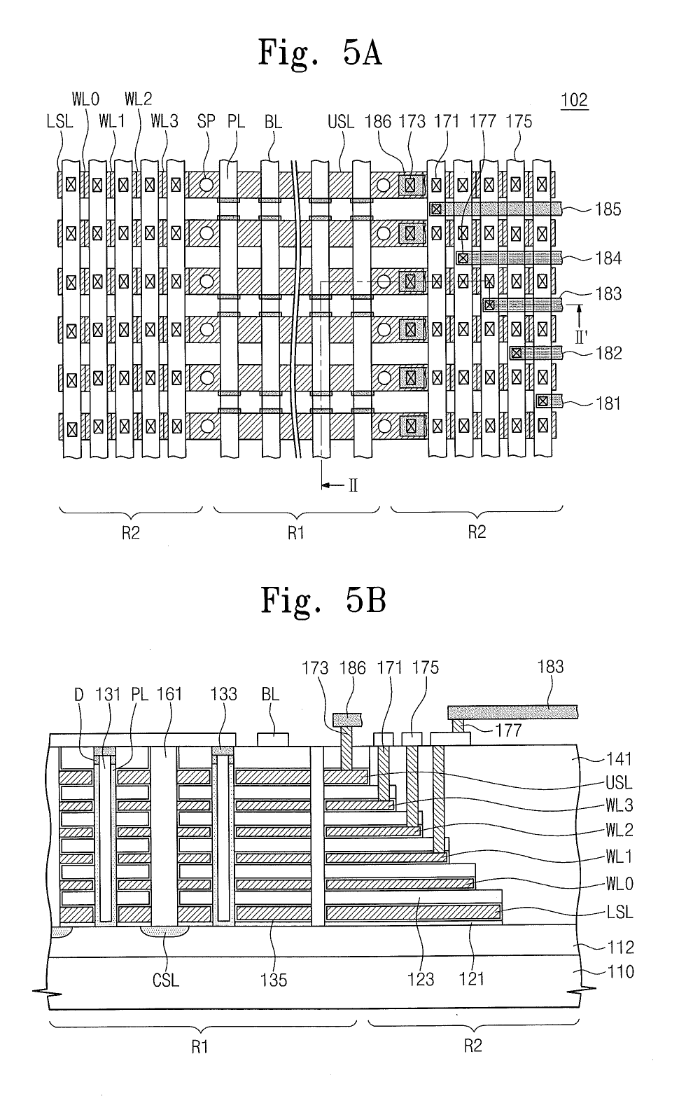

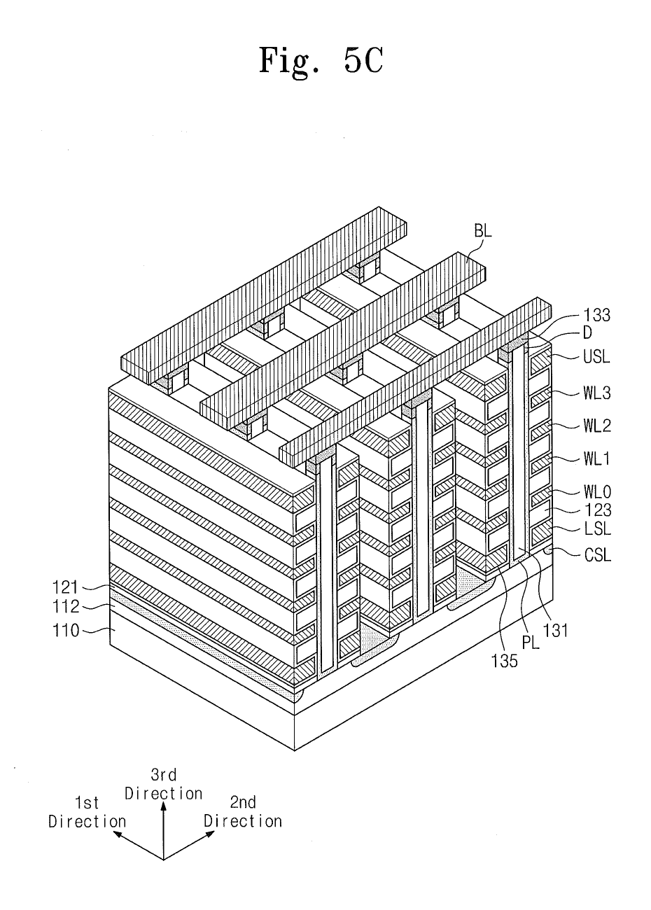

FIG. 5A is a portion of a layout of a three-dimensional semiconductor device 102 according to another embodiment of the inventive concept. FIG. 5B is a sectional view taken along the line II-II′ of FIG. 5A. FIG. 5C is a perspective view of a first region R1 of FIG. 5A. Referring to FIGS. 5A through 5C, the three-dimensional semiconductor device 102 will be described. Detailed description of overlapping technical features described with reference to FIGS. 4A through 4D will be omitted and only the differences will be described in more detail.

Active pillars PL penetrating between the conductive patterns LSL, WL0 to WL3, and USL extending in the first direction and facing each other may be provided. The active pillars PL are provided on the sides of the conductive patterns LSL, WL0 to WL3, and USL to cross over them. The active pillars PL may have a major axis (i.e., extending in the third direction) extending from the substrate 110 to the top. The active pillars PL may be provided being spaced from each other on the facing sides of the conductive patterns LSL, WL0 to WL3, and USL. One active pillar on one side of one conductive pattern may be provided to face another active pillar on one side of another conductive pattern adjacent to the one conductive pattern. An information storage layer 135 may be provided between the word lines WL to WL3 and the active pillars PL.

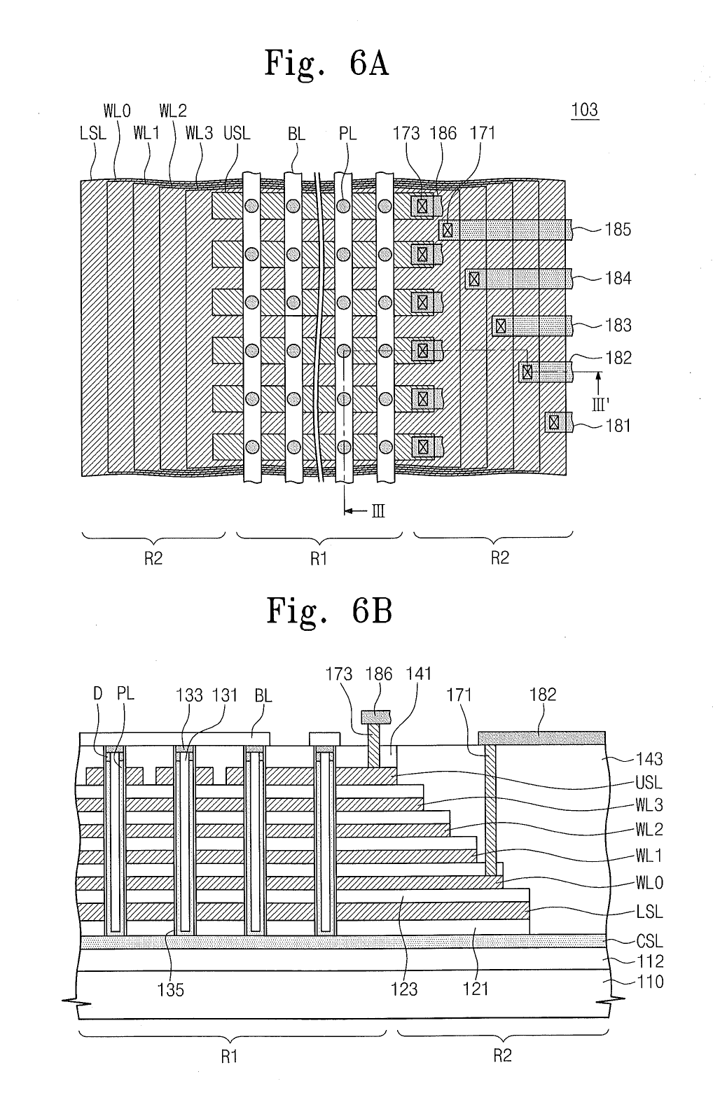

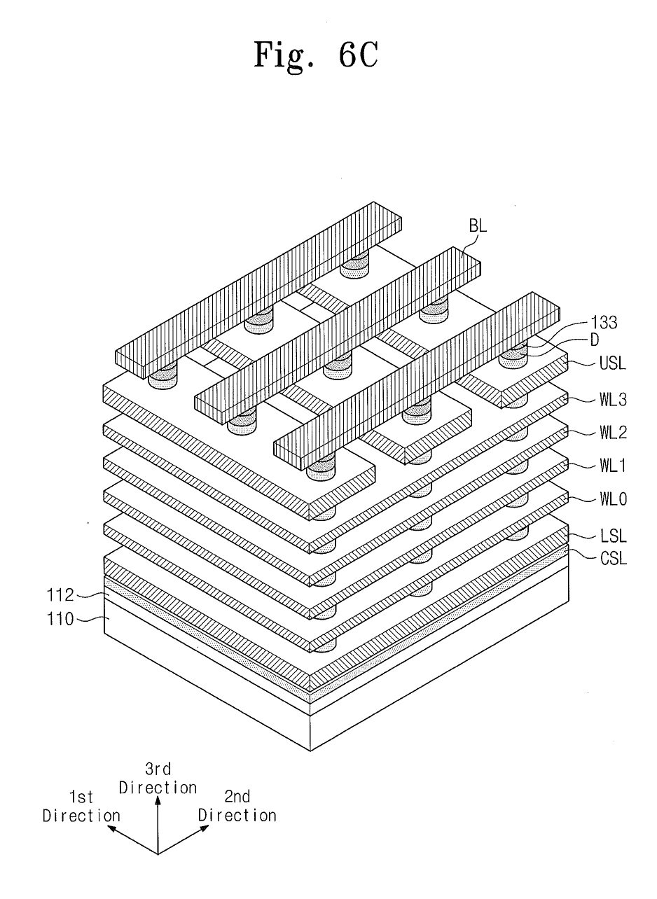

FIG. 6A is a portion of a layout of a three-dimensional semiconductor device 103 according to another embodiment of the inventive concept. FIG. 6B is a sectional view taken along the line II-II′ of FIG. 6A. FIG. 6C is a perspective view of a first region R1 of FIG. 6A. Referring to FIGS. 6A through 6C, the three-dimensional semiconductor device 103 will be described. Detailed description of overlapping technical features described with reference to FIGS. 4A through 4D will be omitted and only the differences will be described in more detail.

A common source line CSL is provided on the top surface of a semiconductor substrate 110. The common source line CSL may have the second conductive type. Active pillars PL penetrating the conductive patterns LSL, WL0 to WL3, and USL of the first region R1 to connect to the common source line CSL of the substrate 110 are provided. The active pillars PL may have a major axis (i.e., extending in the third direction) extending from the substrate 110 to the top. The active pillars PL may include a semiconductor material. The active pillars PL may have a filled cylindrical shape or an empty cylindrical shape (e.g., a macaroni shape). The inside of the macaroni-shaped active pillars may be filled with an insulation material.

The lower selection line LSL at the lowermost layer may have a plate shape or a respectively separated line form. The upper selection lines at the uppermost layer are separated from each other to have a line shape extending in a first direction. The lower selection line LSL and the word lines WL0 to WL3 may have a plate shape. As the conductive patterns LSL, WL0 to WL3, and USL become far from the substrate 110, their areas are reduced and they are stacked. The conductive patterns LSL, WL0 to WL3, and USL may have a stepped structure in the second region R2. For example, in relation to the conductive patterns, the conductive patterns include an upper conductive pattern and a lower conductive pattern under the upper conductive pattern. The lower conductive pattern protrudes to the side more compared to the upper conductive pattern so that a top surface of the lower conductive pattern may be exposed by the upper conductive pattern. The widths of the exposed top surfaces of the conductive patterns may vary according to a distance from the substrate.

First and second conductive pillars 171 and 173 may be provided to connect to the respective exposed top surfaces of the conductive patterns in the second region R2. The upper selection lines USL extending in the first direction may be spaced in the second direction and may be provided in plurality. The plurality of upper selection lines USL may be respectively connected to the third conductive lines 186 extending in the first direction through the second conductive pillar 173 penetrating the first interlayer insulation layer 141. The lower selection line LSL may be connected to the first conductive line 181 extending in the first direction by the first conductive pillar 171 penetrating the second interlayer insulation layer 143. The word lines WL0 to WL3 may be respectively connected to the second conductive lines 182 to 185 extending in the first direction by the first conductive pillar 171 penetrating the second interlayer insulation layer 143.

A method of forming a three-dimensional semiconductor device according to the above-mentioned embodiments of the inventive concept will be described.

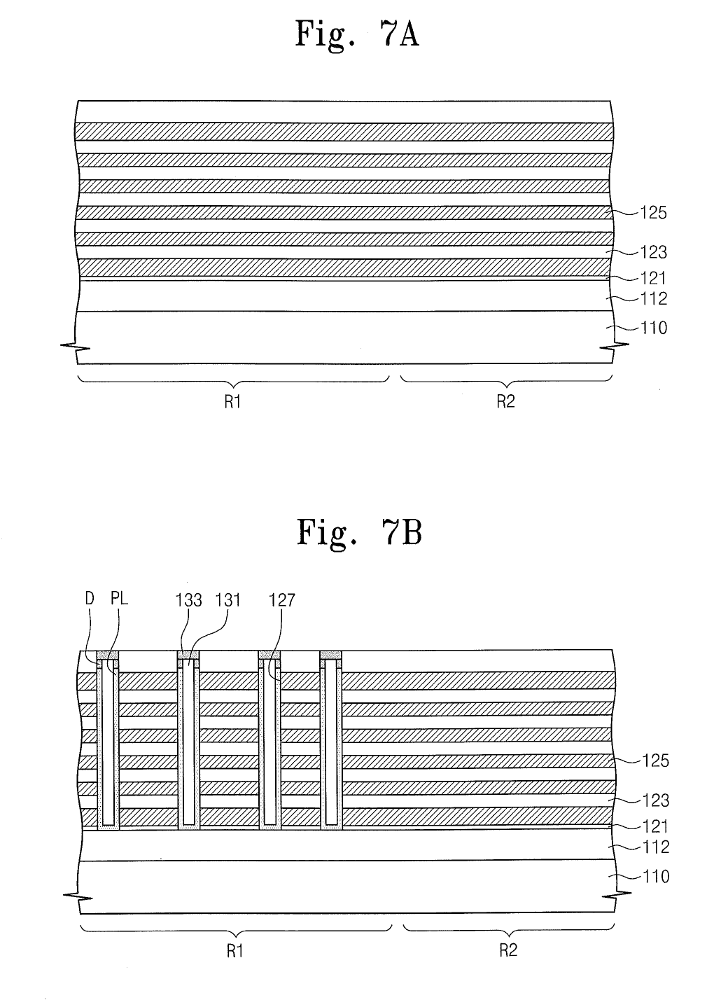

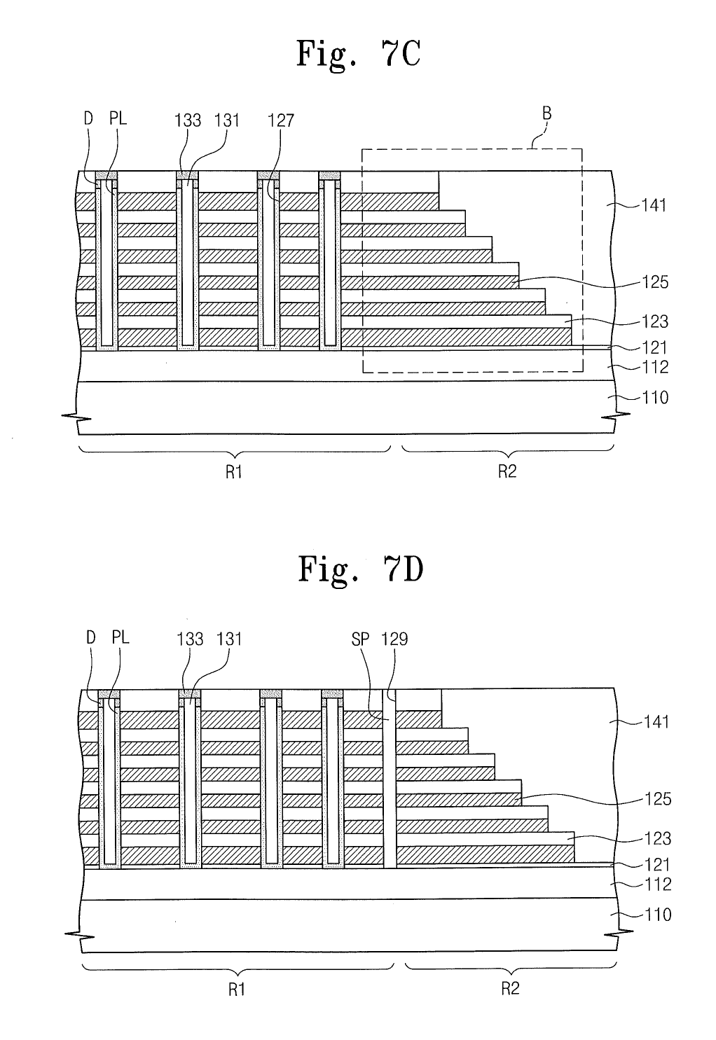

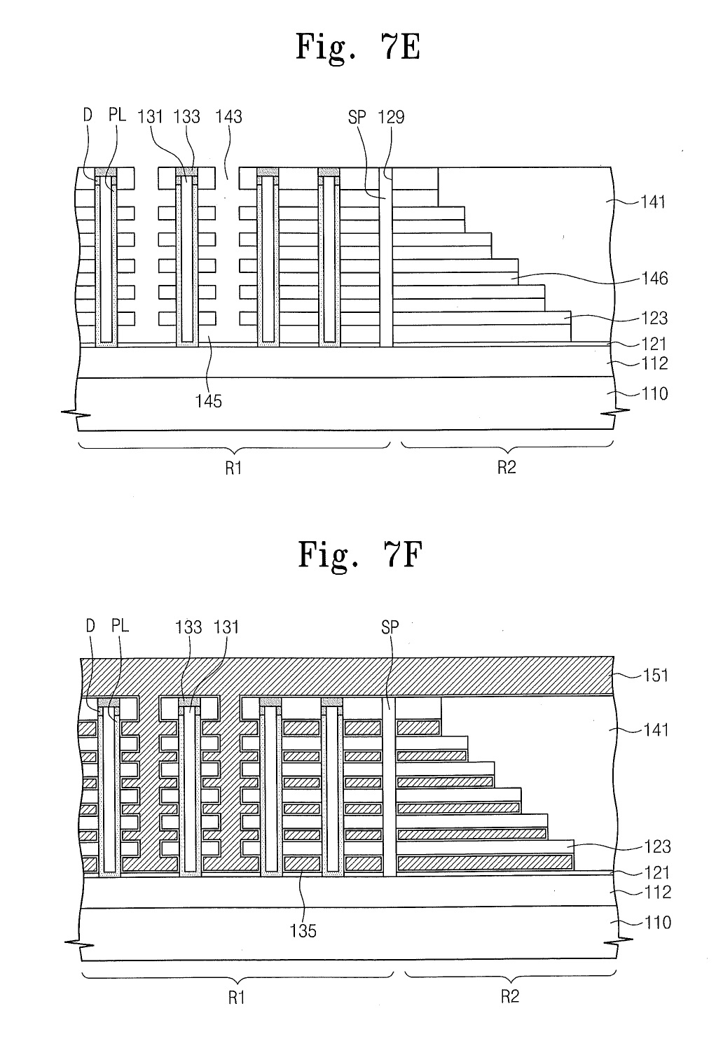

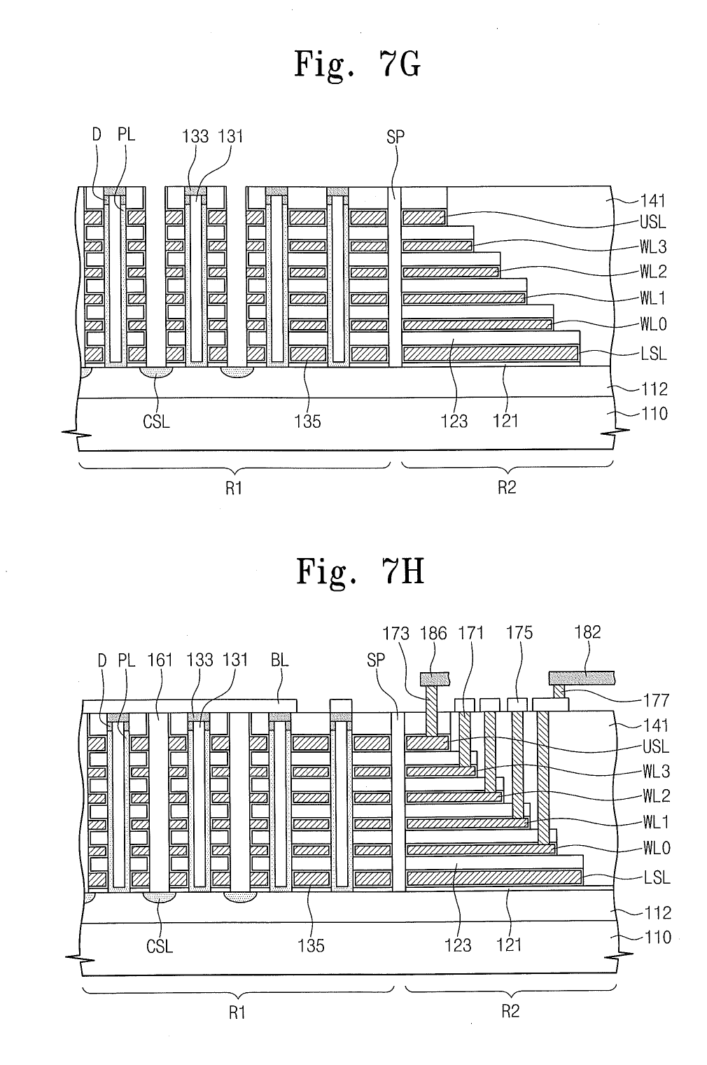

FIGS. 7A through 7H illustrate a method of forming the three-dimensional device described with reference to FIGS. 4A through 4D and are sectional views corresponding to the line I-I′ of FIG. 4A. Referring to FIGS. 4A and 7A, a substrate 110 is provided. In more detail, the substrate 110 includes a first region R1 and a second region R2 disposed at the edge portion of the first region R1. The second region R2 may be provided to the circumference of the first region R1. A well region 112 may be formed by providing a first conductive type impurity ion in the substrate 110 of the first region R1. The well region 112 may be formed through an impurity ion implantation process. The well region 112 may be formed on an entire first region R1 in terms of a plane. A buffer dielectric layer 121 may be formed on a substrate 110 having the well region 112. The buffer dielectric layer 121 may be a silicon oxide layer. The buffer dielectric layer 121 may be formed by a thermal oxide process, for example. First material layers 123 and second material layers 125 are alternately stacked on the buffer dielectric layer 121 and then are provided. A material of the lowermost layer contacting the buffer dielectric layer 121 may be the second material layer 125. A material layer of the uppermost layer may be the first material layer 123. The second material layers of the lowermost layer and the uppermost layer may be formed thicker than the second material layers therebetween. The first material layers 123 may be an insulation layer. The first material layer 123 may include a silicon oxide layer. The second material layer 125 may include a material having a different wet etching property with respect to the buffer dielectric layer 121 and the first material layers 123. The second material layers 125 may include a silicon nitride layer or a silicon oxynitride layer. The first material layers 123 and the second material layers 125 may be formed through a chemical vapor deposition (CVD) method, for example.

Referring to FIG. 7B, active pillars PL penetrating the buffer dielectric layer 121, the first material layers 123, and the second material layers 124 to connect to the substrate 110 are formed in the first region R1. The forming of the active pillars PL will be described with an example. Channel holes 127 penetrating the buffer dielectric layer 121, the first material layers 123, and the second material layers 125 are formed and a channel semiconductor layer of the first conductive type is formed in the channel holes 127. In one embodiment, the channel semiconductor layer is formed not to completely fill the channel holes and an insulation material is formed on the channel semiconductor layer to completely fill the channel holes. The channel semiconductor layer and the insulation material are planarized so that a first material layer of the uppermost layer is exposed. Accordingly, cylindrical active pillars PL of which empty inside is filled with a filling insulation layer 131 may be formed. In another embodiment, the channel semiconductor layer may be formed to fill the channel holes 127. In this case, the filling insulation layer may not be required.

The top of the active pillars PL is recessed so that it may be lower than the first material layer 123 of the uppermost layer. Capping semiconductor patterns 133 may be formed in the channel holes where the active pillars PL are recessed. A second conductive type impurity ion is implanted on the upper portion of the active pillars PL so that drain regions D may be formed. Simultaneously, the second conductive type impurity ion may be implanted on the capping semiconductor patterns 133.

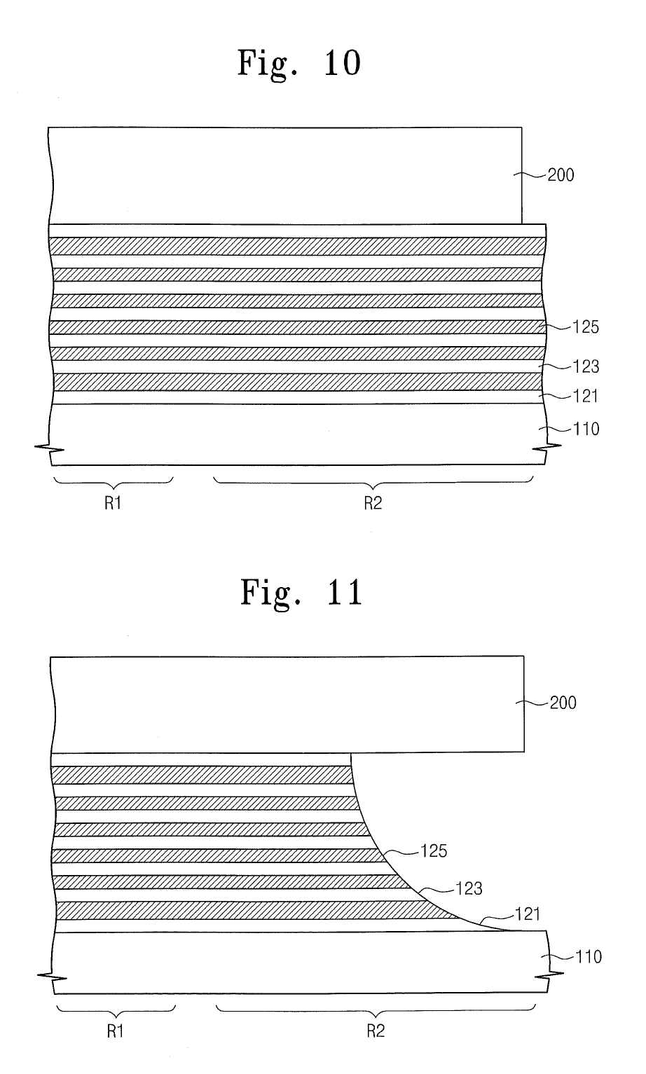

Referring to FIG. 7C, a stepped structure may be formed by patterning the first material layers 123 and the second material layers 125 of the second region R2. The first material layers 123 and the second material layers 125 of the stepped structure may be formed with a plate shape in a plan view. A region B illustrates a stacked pattern of the stepped structure and a method of forming the stacked pattern will be described in more detail with reference to FIGS. 10 through 29.

A first interlayer insulation layer 141 covering the first material layers 123 and the second material layers 125 of the stepped structure in the second region R2 is formed. The first interlayer insulation layer 141 may be formed of a dielectric material having an etch selectivity with respect to the second material layers 125. For example, the first interlayer insulation layer 141 may be formed of the same material as the first material layer 123. For example, the first interlayer insulation layer 141 may be planarized. The planarization process of the first interlayer insulation layer 141 may be performed using the capping semiconductor pattern 133 as an etch stop layer.

According to embodiments described with reference to FIGS. 7A through 7C, after the forming of the active pillars PL, the first material layers 123 and the second material layers 125 of the second region R2 may be formed with a stepped structure. Unlike this, after the forming of the first material layers 123 and the second material layers 125 of the second region R2 with a stepped structure and the forming of the first interlayer insulation layer 141, the active pillars PL may be formed.

Referring to FIG. 7D, supporters SP penetrating the first and second material layers 123 and 125 are formed. If described in more detail, dummy holes 129 for forming the supporters SP in the second region R2 are formed. The dummy holes 129 may expose the surface of the substrate 110. The supporters SP of a pillar shape may be formed by filling an insulation material in the dummy holes 129 and planarizing the top. The supporters SP may be formed of a material having an etch selectivity with respect to the second material layers. For example, the supporters SP may be formed of a silicon oxide layer. In FIG. 7D, it is shown that the supporters SP are formed in the second region R2 but are not limited thereto, so that they may be formed in the first region R1.

Referring to FIG. 7E, grooves 143 spaced from each other and extending in the first direction are formed by continuously patterning the first material layers 123 and the second material layers 125. An empty space 145 is formed by selectively removing the second material layers 125 exposed to the grooves 143. The empty space 145 corresponds to a portion where the second material layers 125 are removed. When the second material layers 125 include a silicon nitride layer, the removing process may be performed by using an etching solution with phosphoric acid. Portions of the side of the active pillars PL are exposed by the empty space 145. The empty space 135 may include an empty space extension portion 146 extending in the second region R2 by a stepped structure of the second material layers 125 in the second region R2.

Referring to FIG. 7F, an information storage layer 135 is conformally formed on the empty space 145. The information storage layer 135 may include a tunnel insulation layer contacting the active pillars PL, a charge storage layer on the tunnel insulation layer, and a blocking insulation layer on the charge storage layer. The tunnel insulation layer of FIG. 4D may include a silicon oxide layer. The tunnel insulation layer may be formed by thermally oxidizing the active pillars PL exposed to the empty space 145. Unlike this, the tunnel insulation layer may be formed through an atomic layer deposition method. The charge storage layer and the blocking dielectric layer may be formed through an atomic layer deposition method and/or a chemical vapor deposition method of excellent step coverage.

A conductive layer 151 filling the empty space 145 is formed on the information storage layer 135. The conductive layer 151 may fill completely or partially the grooves 143. The conductive layer may be formed of at least one of doped silicon, tungsten, metal nitride layers, and metal silicides. The conductive layer 151 may be formed through an atomic layer deposition method.

Referring to FIG. 7G, the conductive layer 151 formed at the external of the empty space 145 is removed. Accordingly, conductive patterns are formed in the empty space 145. The conductive patterns may include upper selection lines USL, word lines WL0 to WL3, and lower selection lines LSL. By an empty space extension portion 146 extending in the second region R2, each of the conductive patterns USL, WL0 to WL3, and LSL has an extension portion extending into the second region R2. In the extension portion of the conductive patterns USL, WL0 to WL3, and LSL, a lower conductive pattern protrudes to the side more compared to an upper conductive pattern so that the top surface of the lower conductive pattern may be exposed by the upper conductive pattern. The substrate 110 may be exposed by removing a conductive layer 151 on the grooves 143. The second conductive type impurity ion is implanted on the exposed substrate 110 so that a common source line CSL may be formed. The first material layers 123 may be the insulation patterns between the conductive patterns LSL, WL0 to WL3, and LSL.

Referring to FIGS. 4A and 7H, an insulation separation pattern 161 filling the grooves 143 is formed. First conductive pillars 171 penetrating the first interlayer insulation layer 141 to contact the word lines and the extension portion (i.e., the exposed top surface) of the lower selection line may be formed.

Bit lines BL extending in the second direction are formed on the first interlayer insulation layer 141 so that they contact the capping semiconductor pattern 133 on the active pillars PL. Simultaneously, a connection pattern 175 extending in the second direction is formed on the first interlayer insulation layer 141 so that it may contact the first conductive pillars 171. A second interlayer insulation layer (not shown) may be formed on the bit lines BL and the connection pattern 175. Second conductive pillars 173 penetrating the second interlayer insulation layer to contact an extension portion of the upper selection lines USL may be formed. Simultaneously, third conductive pillars 177 penetrating the second interlayer insulation layer to contact the connection pattern 175 may be formed. A first conductive line 181, second conductive lines 182 to 185, and a third conductive line 186, which contact the second and third conductive pillars 173 and 177 and extend in the first direction, may be formed on the second interlayer insulation layer.

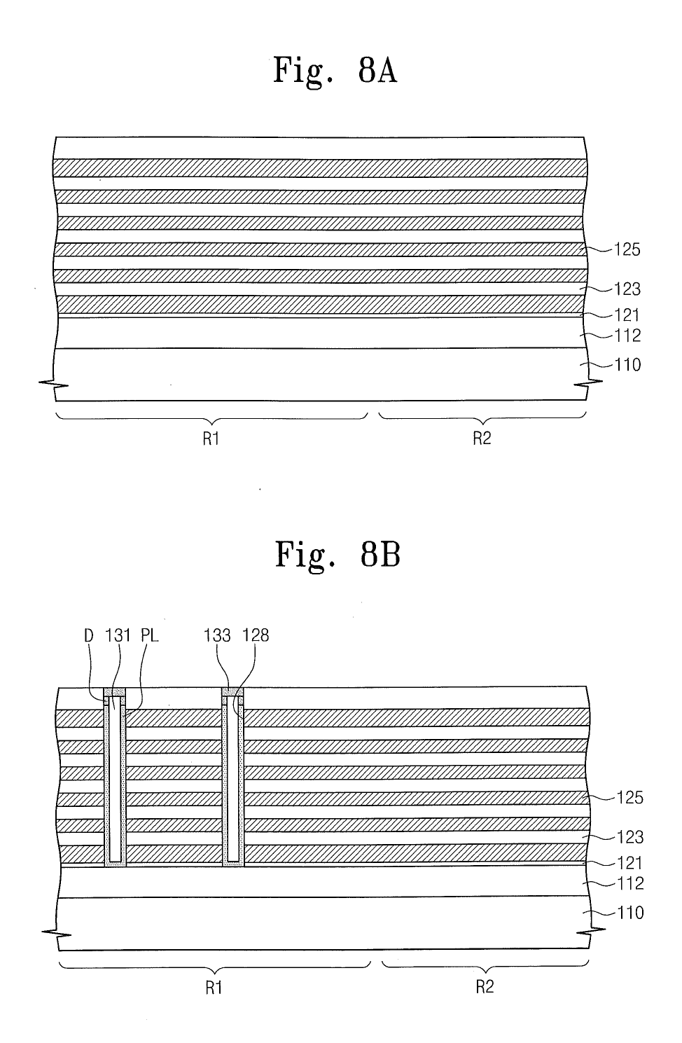

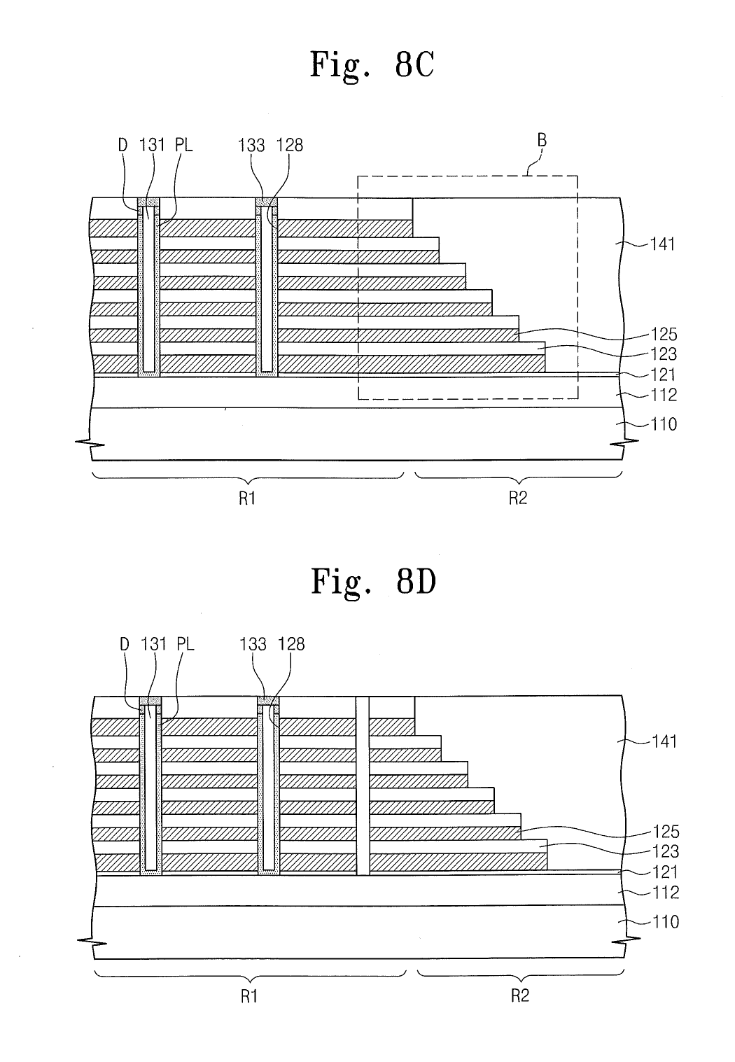

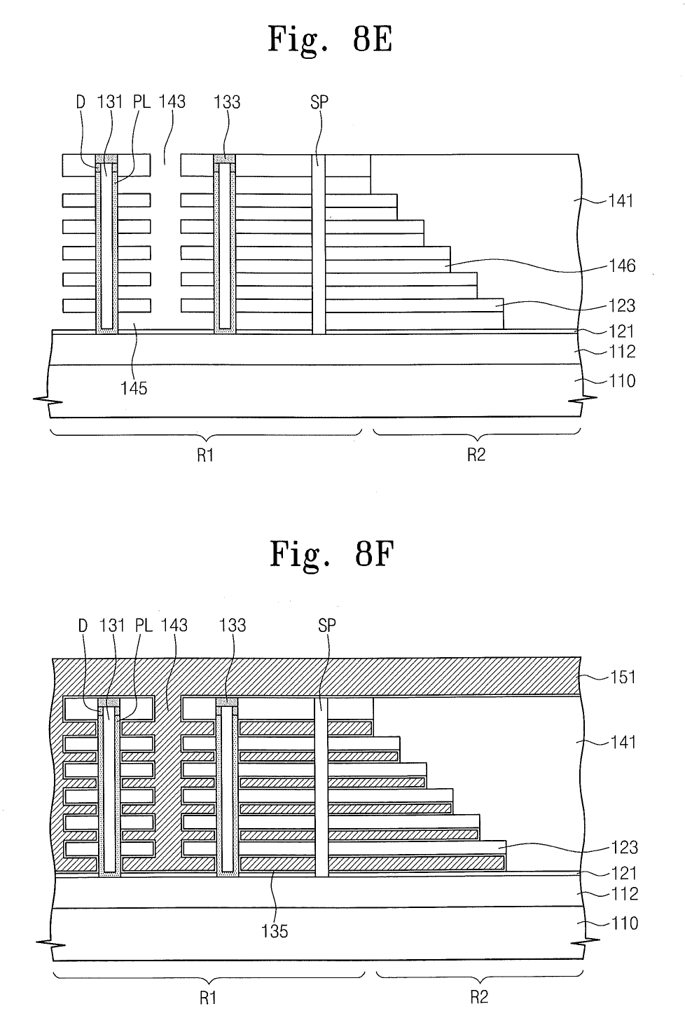

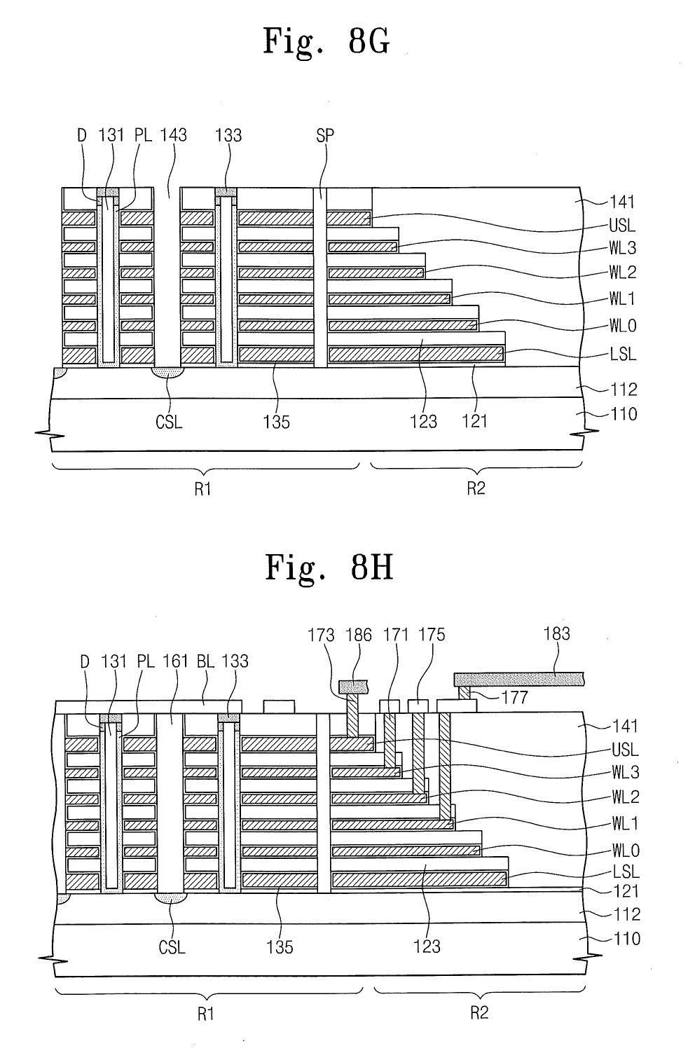

FIGS. 8A through 8H illustrate a method of forming the three-dimensional semiconductor device described with reference to FIGS. 5A through 5C and are sectional views taken along the line II-II′ of FIG. 5A. Detailed description of overlapping technical features described with reference to FIGS. 7A through 7H will be omitted and only the differences will be described in more detail.

Referring to FIGS. 5A and 8A, as described with reference to FIG. 7A, a buffer dielectric layer 121, first material layers 123, and second material layers 125 are provided on a substrate 110 having a well region 112. Referring to FIGS. 5A and 8B, active pillars PL penetrating the buffer dielectric layer 121, the first material layers 123, and the second material layers 125 to connect to the substrate 110 are formed in the first region R1. The forming of the active pillars PL will be described with an example. A plurality of through regions 128 exposing the substrate are formed by patterning the buffer dielectric layer 121, the first material layers 123, and the second material layers 125. The through regions 128 may be a trench extending in the first direction to expose the substrate 110.

A channel semiconductor layer covering the through regions 128 is formed. In one embodiment, the channel semiconductor layer is formed not to completely fill the through regions and an insulation material is formed on the channel semiconductor layer to completely fill the through regions. The channel semiconductor layer and the insulation material are planarized so that a first material layer of the uppermost layer may be exposed. In another embodiment, the channel semiconductor layer may be formed to fill the through regions. In this case, the filling insulation layer may not be required.

By patterning the channel semiconductor layer, active pillars PL separated into the plurality in the first direction and extending from the substrate 110 to the top are formed in the through regions 128. The channel semiconductor layer may extend in the third direction while crossing over the sides of the first and second material layers. An insulation material 131 may be filled into between the active pillars PL separated in the first direction. The insulation material may be a silicon oxide layer.

The top of the active pillars PL is recessed so that it may be lower than the first material layer 123 of the uppermost layer. Capping semiconductor patterns 133 may be formed in the through regions where the active pillars PL are recessed. A second conductive type impurity ion is implanted on the upper portion of the active pillars PL so that drain regions D may be formed. Simultaneously, the second conductive type impurity ion may be implanted on the capping semiconductor patterns 133.

Referring to FIG. 8C, the first material layers 123 and the second material layers 125 of the second region R2 are patterned to have a stepped structure. The first material layers 123 and the second material layers 125 of the stepped structure may be formed with a plate shape in a plan view. A region B illustrates a stacked pattern of the stepped structure and a method of forming the stacked pattern will be described with reference to FIGS. 10 through 29.

A first interlayer insulation layer 141 covering the first material layers 123 and the second material layers 125 of the stepped structure in the second region R2 is formed. The first interlayer insulation layer 141 may be formed of a dielectric material having an etch selectivity with respect to the second material layers 125. For example, the first interlayer insulation layer 141 may be formed of the same material as the first material layer 123. For example, the first interlayer insulation layer 141 may be planarized. The planarization process of the capping insulation layer may be performed using the capping semiconductor pattern 133 as an etch stop layer. According to embodiments described with reference to FIGS. 8A through 8C, after the forming of the active pillars PL, the first material layers 123 and the second material layers 125 of the second region R2 is formed with a stepped structure. Unlike this, after the forming of the first material layers 123 and the second material layers 125 of the second region R2 with a stepped structure and the forming of the first interlayer insulation layer 141, the active pillars PL may be formed.

Referring to FIG. 8D, as described with reference to FIG. 7D, supporters SP penetrating the first and second material layers 123 and 125 are formed. Referring to FIG. 8E, grooves 143 spaced from each other and extending in the first direction are formed by continuously patterning the first material layers 123 and the second material layers 125. An empty space 145 is formed by selectively removing the second material layers 125 exposed to the grooves 143. The empty space 145 corresponds to a portion where the second material layers 125 are removed. By the empty space 145, portions of the side of the active pillars PL are exposed. By a stepped structure of the second material layers 125 in the second region R2, the empty space 145 may have an empty space extension portion 146 extending in the second region R2.

Referring to FIG. 8F, as described with reference to FIG. 7F, an information storage layer 135 may be conformally formed on the empty space 145. A conductive layer 151 filling the empty space 145 is formed on the information storage layer 135. The conductive layer 151 may completely or partially fill the grooves 143.

Referring to FIG. 8G, the conductive layer 151 at the external of the empty space 145 is removed. Accordingly, conductive patterns are formed in the empty space 145. The conductive patterns may include upper selection lines USL, word liens WL0 to WL3, and a lower selection line LSL. In the extension portion of the conductive patterns USL, WL0 to WL3, and LSL, a lower conductive pattern protrudes to the side more compared to an upper conductive pattern so that the top surface of the lower conductive pattern may be exposed by the upper conductive pattern. The substrate 110 may be exposed by removing a conductive layer 151 on the grooves 143. The second conductive type impurity ion is implanted on the exposed substrate 110 so that a common source line CSL may be formed.

Referring to FIGS. 5A and 8H, an insulation separation pattern 161 filling the grooves 143 is formed. First conductive pillars 171 penetrating the first interlayer insulation layer 141 to contact the word lines and the extension portion of the lower selection line may be formed. Bit lines BL extending in the second direction are formed on the first interlayer insulation layer 141 so that they contact the capping semiconductor pattern 133 on the active pillars PL. Simultaneously, a connection pattern 175 extending in the second direction is formed on the first interlayer insulation layer 141 so that it may contact the first conductive pillars 171. A second interlayer insulation layer (not shown) may be formed on the bit lines BL and the connection pattern 175. Second conductive pillars 173 penetrating the second interlayer insulation layer to contact an extension portion of the upper selection lines USL may be formed. Simultaneously, third conductive pillars 177 penetrating the second interlayer insulation layer to contact the connection pattern 175 may be formed. A first conductive line 181, second conductive lines 182 to 185, and a third conductive line 186, which contact the second and third conductive pillars 173 and 177 and extend in the first direction, may be formed on the second interlayer insulation layer.

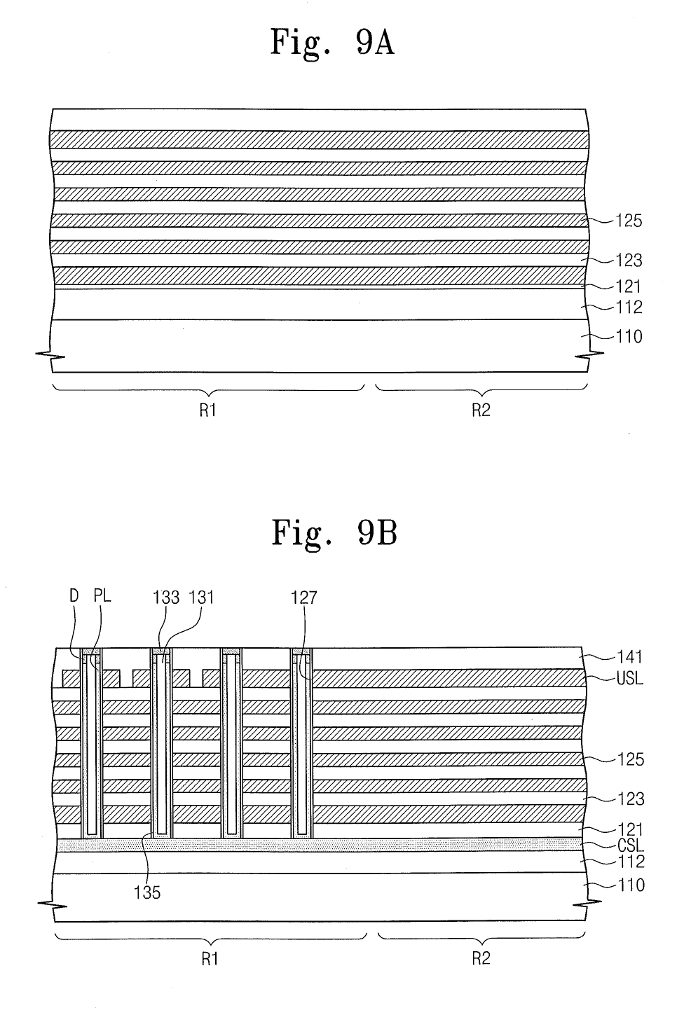

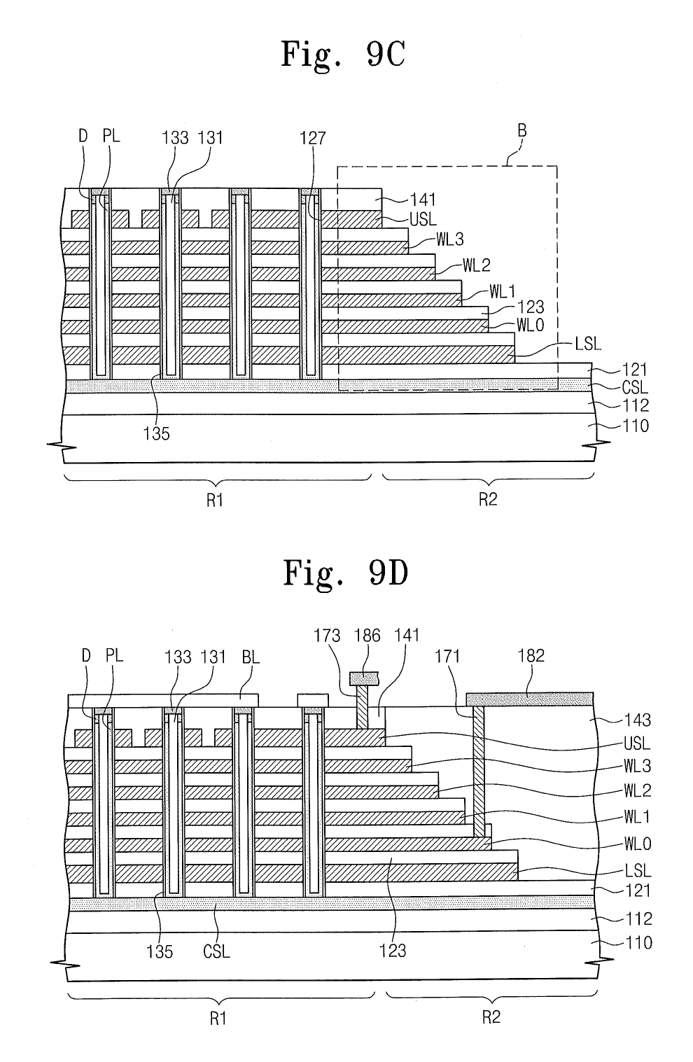

FIGS. 9A through 9D illustrate a method of forming the three-dimensional semiconductor device described with reference to FIGS. 6A through 6C and are sectional views taken along the line III-III′ of FIG. 6A. Detailed description of overlapping technical features described with reference to FIGS. 7A through 7H will be omitted and only the differences will be described in more detail.

Referring to FIGS. 6A and 9A, a substrate 110 is provided. In more detail, the substrate 110 includes a first region R1 and a second region R2 disposed at the edge portion of the first region R1. The second region R2 may be provided to the circumference of the first region R1.

A well region 112 may be formed by providing a first conductive type impurity ion in the substrate 110 of the first region R1. The well region 112 may be formed through an impurity ion implantation process. The well region 112 may be formed on an entire first region R1 in terms of a plane. The second conductive type impurity ion of a high concentration is provided so that a common source line CSL may be formed.

A buffer dielectric layer 121 may be formed on the substrate 110. The buffer dielectric layer 121 may be a silicon oxide layer. First material layers 123 and second material layers 125 are alternately stacked on the buffer dielectric layer 121 and then provided. The first material layers may be an insulation layer. The first material layers 123 may include a silicon oxide layer, for example. The second material layers 125 may include a material having a different wet etching property with respect to the buffer dielectric layer 121 and the first material layers 123. The second material layers may be formed of polycrystalline silicon doped with the second conductive type impurity or metallic materials, for example. The first material layers 123 and the second material layers 125 may be formed through a CVD process, for example.

Referring to FIGS. 6A and 9B, upper selection lines USL extending in a first direction may be formed by pattering a second material layer of the uppermost layer among the second material layers. A first interlayer insulation layer 141 covering the upper selection lines USL is formed.

Openings (i.e., channel holes 127) penetrating the buffer dielectric layer 121, the first material layers 123, the second material layers 125, and the first interlayer insulation layer 141 are formed in the first region R1 and an information storage layer 135 is formed on the inner walls of the channel holes 127. The forming of the information storage layer 135 may include sequentially forming a blocking insulation layer, a charge storage layer, and a tunnel insulation layer. The blocking insulation layer, the charge storage layer, and the tunnel insulation layer may be formed through an atomic layer deposition method, for example. A spacer (not shown) covering the information storage layer 135 on the inner walls of the channel holes 127 is formed. Using the spacer as a mask, the information storage layer covering the substrate 110 is partially etched so that substrate 110 may be exposed. The spacer may be formed of an insulation layer and may be removed after the forming of the information storage layer 135.

Active pillars PL may be formed on the exposed substrate 110 and the information storage layer 135. A method of forming the active pillars PL will be described with an example. A channel semiconductor layer may be formed on the information storage layer 135 on the inner walls of the channel holes 127. In one embodiment, the channel semiconductor layer may be formed not to completely fill the channel holes 127 and an insulation material is formed on the channel semiconductor layer to completely fill the channel holes 127. The channel semiconductor layer and the insulation material are planarized, so that the first interlayer insulation layer 141 may be exposed. Accordingly, cylindrical active pillars PL of which empty inside is filled with a filling insulation layer 131 may be formed. In another embodiment, the channel semiconductor layer may be formed to fill the channel holes 127. In this case, the filling insulation layer may not be required.

The top of the active pillars PL is recessed so that it may be lower than the first material layer 123 of the uppermost layer. Capping semiconductor patterns 133 may be formed in the through regions where the active pillars PL are recessed. A second conductive type impurity ion is implanted on the upper portion of the active pillars PL so that drain regions D may be formed. Simultaneously, the second conductive type impurity ion may be implanted on the capping semiconductor patterns 133.

Referring to FIG. 9C, a stepped structure may be formed by patterning the first material layers 123 and the second material layers 125 of the second region R2. The first material layers 123 and the second material layers 125 of the stepped structure may be formed with a plate shape in a plan view. A region B illustrates a stacked pattern of the stepped structure and a method of forming the stacked pattern will be described in more detail with reference to FIGS. 10 through 29.

The second material layers 125 may be the conductive patterns LSL, WL0 to WL3, and USL. The conductive patterns may include upper selection lines USL, word lines WL0 to WL3, and a lower selection line LSL. Each of the conductive patterns LSL, WL0 to WL3, and USL may have an extension portion extending into the second region R2. In the extension portion of the conductive patterns USL, WL0 to WL3, and LSL, a lower conductive pattern protrudes to the side more compared to an upper conductive pattern so that the top surface of the lower conductive pattern may be exposed by the upper conductive pattern.

According to embodiments described with reference to FIGS. 9A through 9C, after the forming of the active pillars PL, the first material layers 123 and the second material layers 125 of the second region R2 may be formed with a stepped structure. Unlike this, after the forming of the first material layers 123 and the second material layers 125 of the second region R2 with a stepped structure, the active pillars PL may be formed.

Referring to FIG. 9D, a second interlayer insulation layer 143 is formed on the substrate 110. The first interlayer insulation layer 141 may be exposed. First conductive pillars 171 penetrating the second interlayer insulation layer 143 to contact the word lines and an extension portion of the lower selection line may be formed. Bit lines BL extending in the second direction are formed on the first interlayer insulation layer 141 so that they may contact the capping semiconductor pattern 133 on the active pillars PL. Second conductive lines 182 to 185 and a first conductive line 181, which contact the first conductive pillars 171 and extend in the first direction, may be formed on the second interlayer insulation layer 143. A third interlayer insulation layer (not shown) may be formed on the bit lines BL, the second conductive lines, and the first conductive line. Second conductive pillars 173 penetrating the third interlayer insulation layer to contact an extension portion of the upper selection lines USL may be formed. A third conductive line 186 contacting the second conductive pillars 173 and extending in the first direction may be formed on the third interlayer insulation layer. According to the inventive concept, methods of forming a stepped structure in the second region R2 will be described with an example.

FIGS. 10 through 13 illustrate a method of forming a three-dimensional semiconductor device according to an embodiment of the inventive concept and are sectional views corresponding to the region B of FIGS. 7C, 8C, and 9C. Referring to FIG. 10, a substrate 110 is provided. In more detail, the substrate 110 includes a first region R1 and a second region R2 disposed at the edge portion of the first region R1. The second region R2 may be provided at the circumference of the first region R1. The substrate 110 includes the well region but is omitted in FIG. 10.

A buffer dielectric layer 121 is provided on the substrate 110. The buffer dielectric layer 121 may be a silicon oxide layer. A thickness of the buffer dielectric layer 121 may vary depending on an example of a three-dimensional semiconductor device. First material layers 123 and second material layers 125 are alternately stacked on the buffer dielectric layer 121 and then are provided. The lowermost material layer may be the second material layer 125. The first material layers 123 may be an insulation layer, for example. The second material layer 125 may include a material having a different wet etching property with respect to the buffer dielectric layer 121 and the first material layers 123. The second material layers 125 may include a silicon nitride layer, a silicon oxynitride layer, or polycrystalline silicon. A thickness of the first material layers 123 and the second material layers 125 may be about several hundred A. A mask pattern 200 is formed on the uppermost first material layer. The mask pattern 200 may be a photoresist pattern, for example. The mask pattern 200 may expose a partial region of the second region R2 in operation S11.

Referring to FIG. 11, the stacked first material layers 123 and second material layers 125 in the partial region exposed by the mask pattern 200 are isotropically etched through a first etching process so that the substrate 100 may be exposed in operation S12. The first etching process may be a wet etching process having an approximately equivalent (or equivalent) etch rate with respect to the first and second material layers 123 and 125. The same etch rate may mean completely identical one and one with a manufacturing process tolerance. When the first material layer 123 is a silicon oxide layer and the second material layer 125 is a silicon nitride layer, the first etching process may be performed using a solution including NH₄F and HF. When the first material layer 123 is a silicon oxide layer and the second material layer 125 is polycrystalline silicon, the first etching process may be performed using a solution including HF and nitric acid or an alkaline solution including ammonia and hydrogen peroxide.

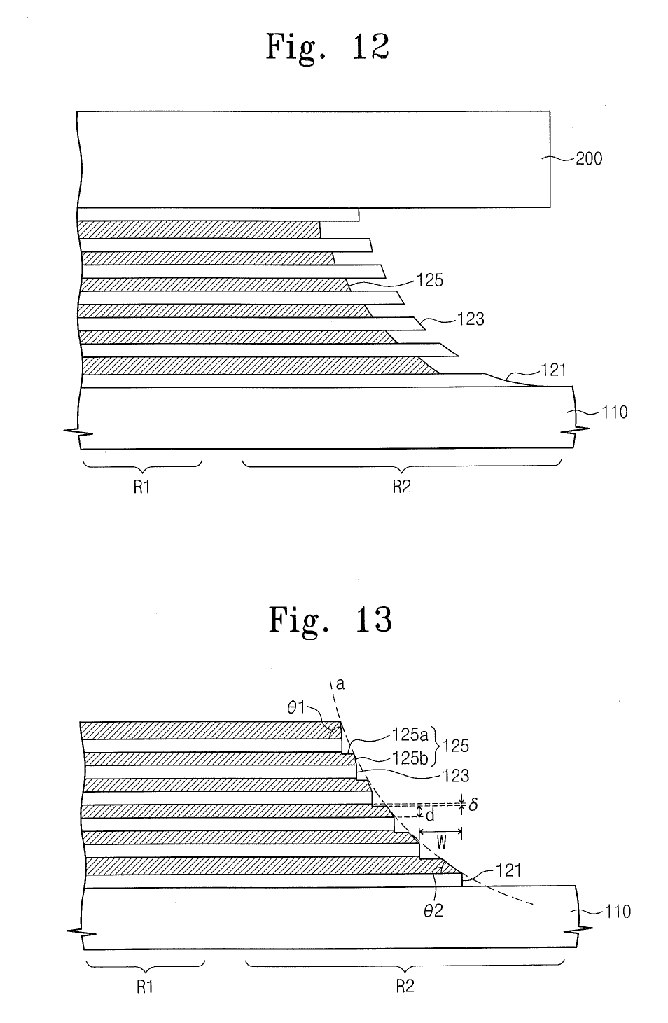

Referring to FIG. 12, the second material layers 125 are isotropically etched through a second etching process in operation S13. The second etching process may include a wet etching process having a higher etch rate with respect to the second material layers 125 than the first material layers 123. In the drawings, although it is illustrated that the first material layers 123 are not etched during the second etching process, its portion may be etched substantially. When the first material layer 123 is a silicon oxide layer and the second material layer 125 is a silicon nitride layer, the second etching process may be performed using a solution including phosphoric acid, a solution including HF, or a solution dilute sulfuric acid. When the first material layer 123 is a silicon oxide layer and the second material layer 125 is polycrystalline silicon, the second etching process may be performed using a solution including HF and nitric acid or an alkaline solution including ammonia and hydrogen peroxide.

In FIGS. 11 and 12, it is described that the order of the first etching process and the second etching process is sequential. However, the inventive concept is not limited thereto and thus the first and second etching processes may be performed simultaneously. The performing of the first and second etching processes simultaneously may include a wet etching process during which the first material layers 123 are removed simultaneously although an etch rate is higher with respect to the second material layers 125 than the first material layers 123.

Referring to FIG. 13, the mask pattern 200 is removed. Through a third etching process, the first material layer 123 may be isotropically etched using the etched second material layers 125 as a mask in operation S14. The third etching process may include an etch back process. Accordingly, the first material layers 123 are interposed, are spaced from each other, and are vertically stacked on the substrate 110. In the second region R2, the second material layers 125 may be formed, where a lower portion protrudes to the side more compared to an upper portion so that the top surfaces of the lower portion may be exposed by the upper portion.

The second material layers 125 may have a stacked pattern of a stepped shape where the top surfaces 125a and the sides 125b are exposed. Forms obtained by the top surface 125a and the side 125b of each second material layer 125 may vary according to a distance from the substrate 110.

The widths W of the exposed top surfaces 125a of the second material layers 125 may be reduced progressively farther from the substrate 110. The top surface of the second material layer (e.g., the uppermost second material layer) farthest from the substrate 110 may have a greatly smaller width than the top surface of the second material layer (e.g., the lowermost second material layer) closest to the substrate 110. A gradient of the sides 125b of the second material layers 125 is increased progressively farther from the substrate 110. A side of the second material layer (e.g., the uppermost second material layer) farthest to the substrate 110 may have a greater gradient than a side of the second material layer (e.g., the lowermost second material layer) closest to the substrate 110 (θ₂>θ₁). An extension line a which connects the sides 125b of the second material layers 125 may be an arc. According to the isotropic etching process, since the exposed top surfaces are over-etched, a thickness d in the second region R2 of the second material layers 125 may be thinner than that in the first region R1. A thickness of the lower second material layers except the uppermost second material layer in the second region R2 may be thinner by predetermined values 8 than that in the first region Rt. The predetermined values 8 of the lower conductive patterns may be the same. It is understood that the sameness of the predetermined values 8 may mean that it is in a tolerance range of the anisotropic etching process.

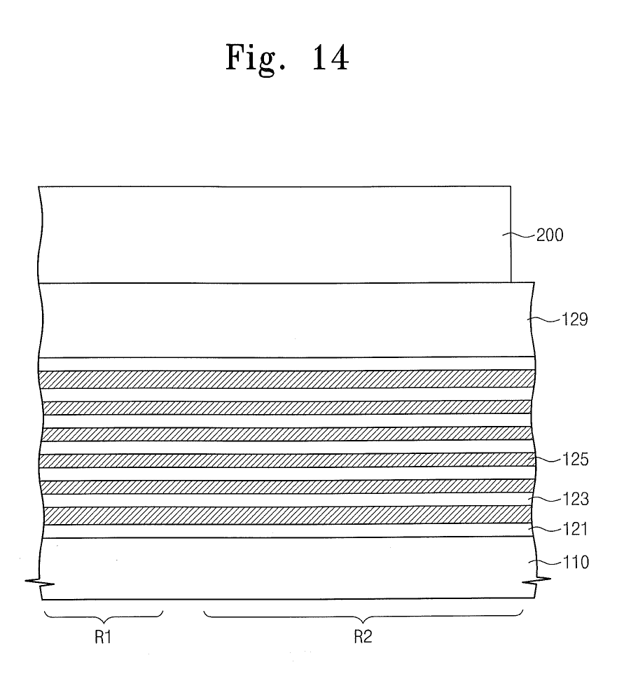

Another embodiment of the inventive concept is described. FIGS. 14 through 17 illustrate a method of forming a three-dimensional semiconductor device according to another embodiment of the inventive concept and are sectional views corresponding to the region B of FIGS. 7C, 8C, and 9C. Detailed description of overlapping technical features described with reference to FIGS. 10 through 13 will be omitted and only the differences will be described in more detail.

Referring to FIG. 14, a substrate 110 is provided. In more detail, the substrate 110 includes a first region R1 and a second region R2 disposed at the edge portion of the first region R1. The second region R2 may be provided at the circumference of the first region R1. A buffer dielectric layer 121 is provided on the substrate 110. The buffer dielectric layer 121 may be a silicon oxide layer. A thickness of the buffer dielectric layer 121 may vary depending on an example of a three-dimensional semiconductor device. First material layers 123 and second material layers 125 are alternately stacked on the buffer dielectric layer 121 and then are provided. The lowermost material layer may be the second material layer 125. The first material layers 123 may be an insulation layer, for example. The first material layer 123 may include a silicon oxide layer, for example. The second material layer 125 may include a material having a different wet etching property with respect to the first material layers 123. The second material layers 125 may include a silicon nitride layer, a silicon oxynitride layer, or polycrystalline silicon. An etch buffer layer 129 is formed on the uppermost first material layer. The etch buffer layer 129 may be the same as the first material layers 123 or the second material layers 125. In this case, a thickness of the uppermost first material layer may be thicker than those of other first material layers. A thickness of the etch buffer layer 129 may be more than about 1000 Å. A mask pattern 200 is formed on the etch buffer layer 129. The pattern 200 may be a photoresist pattern, for example. The mask pattern 200 may expose a partial region of the second region R2 in operation S21.

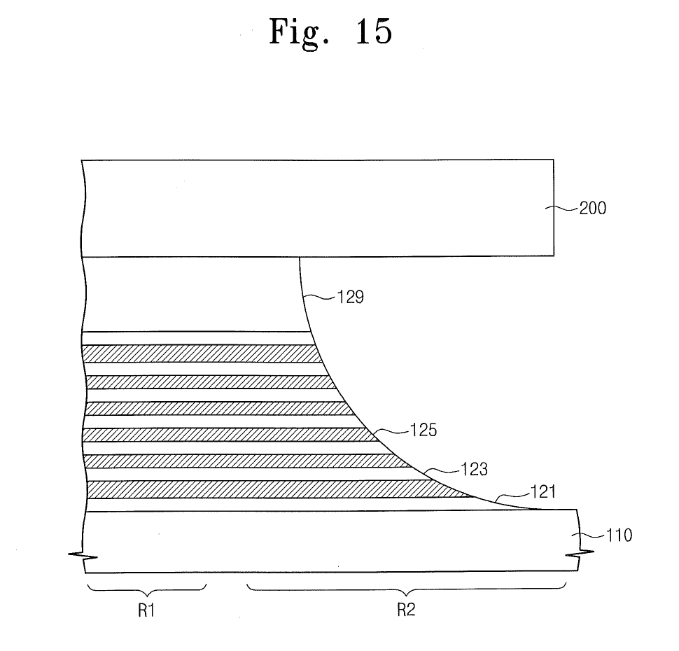

Referring to FIG. 15, the stacked first material layers 123 and second material layers 125 in the partial region exposed by the mask pattern 200 are isotropically etched through a first etching process so that the substrate 100 may be exposed. The first etching process may be a wet etching process having the same etch rate with respect to the first and second material layers 123 and 125 in operation S22.

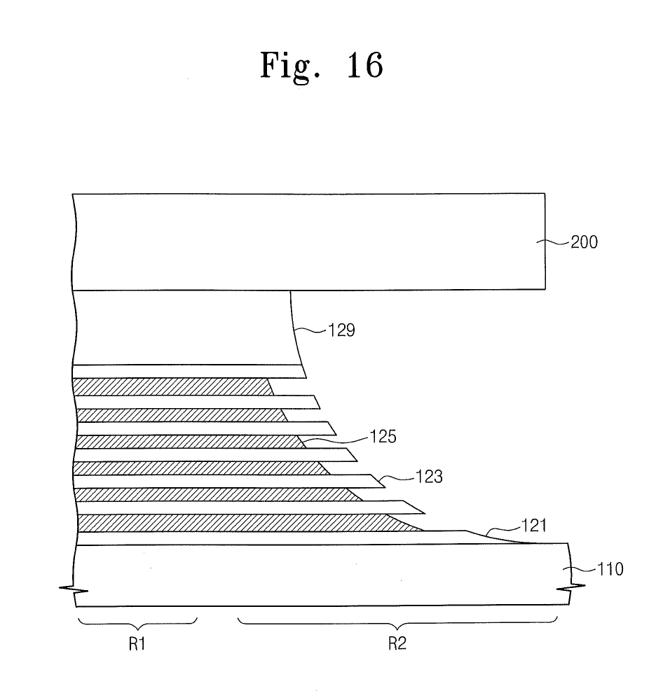

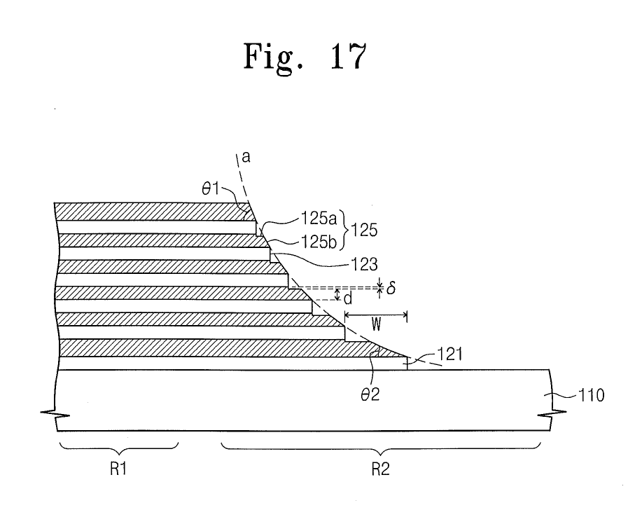

Referring to FIG. 16, the second material layers 125 are isotropically etched through a second etching process in operation S23. The second etching process may include a wet etching process having a higher etch rate with respect to the second material layers 125 than the first material layers 123. In FIGS. 15 and 16, it is described that the order of the first etching process and the second etching process is sequential. However, the inventive concept is not limited thereto and thus the first and second etching processes may be performed simultaneously. The performing of the first and second etching processes simultaneously may include a wet etching process during which the first material layers 123 are removed simultaneously although an etch rate is higher with respect to the second material layers 125 than the first material layers 123.

Referring to FIG. 17, the mask pattern 200 is removed. Through a third etching process, the first material layer 123 may be isotropically etched using the etched second material layers 125 as a mask in operation S24. The third etching process may include an etch back process. Accordingly, the first material layers 123 are interposed, are spaced from each other, and are vertically stacked on the substrate 110. In the second region R2, the second material layers 125 of a stepped structure may be formed, where a lower portion protrudes to the side more compared to an upper portion so that the top surfaces of the lower portion may be exposed by the upper portion. Like one embodiment described with reference to FIG. 13, the second material layers 125 may have a stacked pattern of a stepped structure where their top surfaces 125a and sides 125b are exposed. However, compared to the above-mentioned embodiment, the gradient of the sides 125b of the second material layers 125 may be reduced. Compared to the above-mentioned embodiment, the widths W of the exposed top surfaces 125a of the second material layers 125 may be increased. Moreover, an extension line a connecting the sides 125b of the second material layers 125 may have one arc. The radius of the arc in FIG. 17 may be larger than that in the above mentioned embodiment.

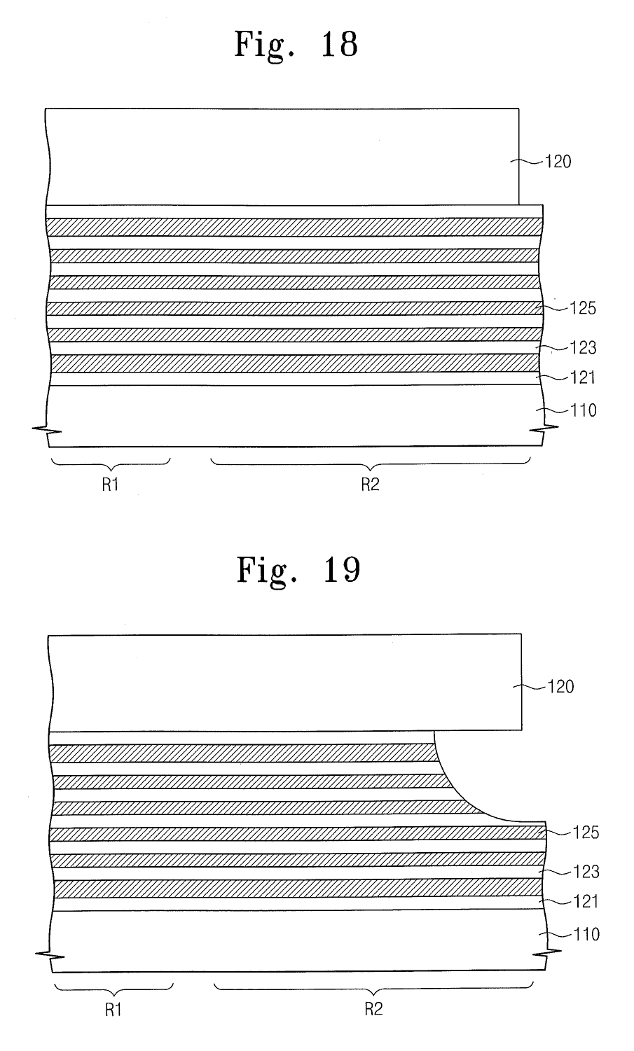

FIGS. 18 through 22 illustrate a method of forming a three-dimensional semiconductor device according to a further another embodiment of the inventive concept and are sectional views corresponding to the region B of FIGS. 7C, 8C, and 9C. Detailed description of overlapping technical features described with reference to FIGS. 10 through 13 will be omitted and only the differences will be described in more detail.

Referring to FIG. 18, a substrate 110 is provided. In more detail, the substrate 110 includes a first region R1 and a second region R2 disposed at the edge portion of the first region R1. The second region R2 may be provided to the circumference of the first region R1 in operation S31. A buffer dielectric layer 121 is provided on the substrate 110. The buffer dielectric layer 121 may be a silicon oxide layer. A thickness of the buffer dielectric layer 121 may vary depending on an example of a three-dimensional semiconductor device. First material layers 123 and second material layers 125 are alternately stacked on the buffer dielectric layer 121 and then are provided. The lowermost material layer may be the second material layer 125. A mask pattern 200 is formed on the uppermost first material layer. The mask pattern 200 may be a photoresist pattern, for example. The mask pattern 200 may expose a partial region of the second region R2 in operation S31.

Referring to FIG. 19, the stacked first material layers 123 and second material layers 125 in the partial region exposed by the mask pattern 200 are isotropically etched through a first etching process in operation S32. Etching times or conditions are adjusted not to expose the substrate 110 due to the first etching process. The first etching process may be a wet etching process having the same etch rate with respect to the first material layers 123 and the second material layers 125.

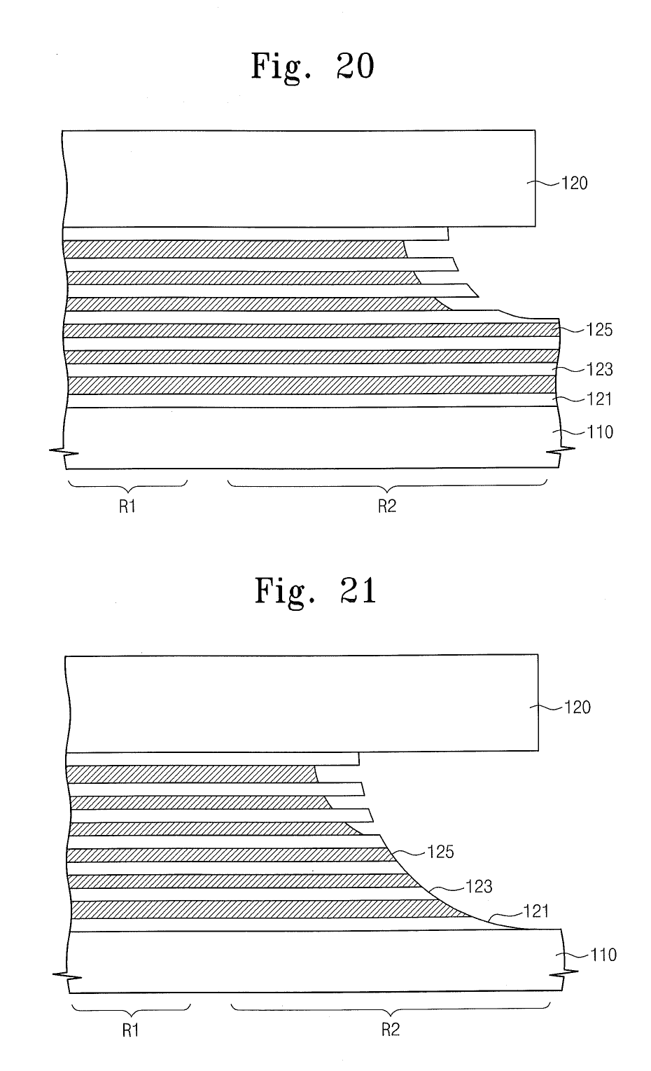

Referring to FIG. 20, the second material layers 125 are isotropically etched through a second etching process in operation S33. The second etching process may include a wet etching process having a higher etch rate with respect to the second material layers 125 than the first material layers 123.

Hereinafter, after the second etching process described with reference to FIG. 20, the substrate may be exposed by performing an etching process (having a smaller etch rate difference with respect to the first and second material layers 123 and 125 than the second etching process) in operation S34.

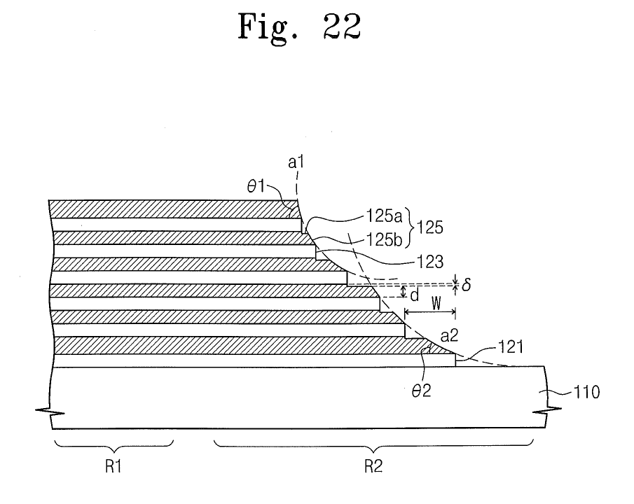

Referring to FIG. 21, the stacked first material layer 123 and second material layers 125 are additionally isotropically etched through a third etching process so that the substrate 110 may be exposed. The third etching process may be a wet etching process having the same etch rate with respect to the first material layers 123 and the second material layers 125. By additionally performing the second etching process described with reference to FIG. 20, the second material layers 125 may be etched. The additional etching process may include a wet etching process having a higher etch rate with respect to the second material layers 125 than the first material layers 123.

Referring to FIG. 22, the mask pattern 200 is removed. Through a fourth etching process, the first material layer 123 may be isotropically etched using the etched second material layers 125 as a mask. The fourth etching process may include an etch back process. Accordingly, the first material layers 123 are interposed, are spaced from each other, and are vertically stacked on the substrate 110. In the second region R2, the second material layers 125 may be formed, where a lower portion protrudes to the side more compared to an upper portion so that the top surfaces of the lower portion may be exposed by the upper portion.

As described with reference to FIG. 13, the second material layers 125 may have a stacked pattern of a stepped structure where their top surfaces 125a and sides 125b are exposed. However, compared to the above-mentioned embodiment of FIG. 13, the widths W of the exposed top surfaces 125a of the second material layers 125 may be increased. Moreover, an extension line connecting the sides 125b of the second material layers 125 may have at least one arc. In more detail, an extension line connecting the sides may have two arcs a1 and a2. The radius of curvature of the arcs may vary. The upper arc (e.g., a1) may have a smaller radius of curvature than a lower arc (e.g., a2). The width of the top surface of the second material layer in a region where the arcs meet may be broader than those of other second material layers.

This embodiment illustrates a process for forming two arcs but the inventive concept is not limited thereto. A process may be provided to form more than two arcs. That is, the substrate is not exposed when the process described with reference to FIG. 21 is performed once but is exposed when the process are performed several times.

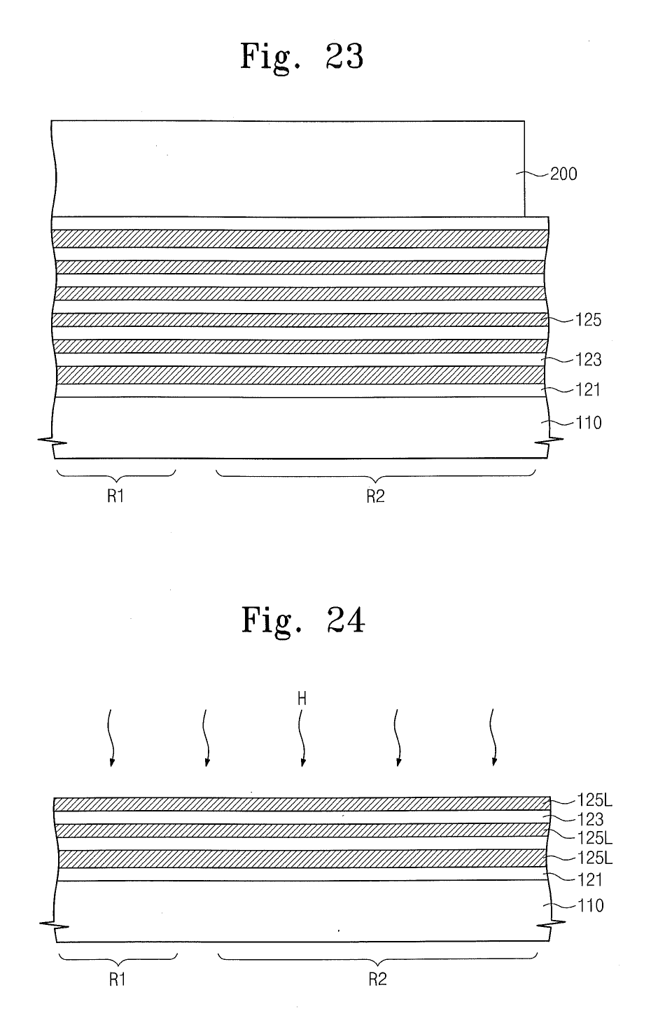

FIGS. 23 through 29 illustrate a method of forming a three-dimensional semiconductor device according to a further another embodiment of the inventive concept and are sectional views corresponding to the region B of FIGS. 7C, 8C, and 9C. Detailed description of overlapping technical features described with reference to FIGS. 10 through 13 will be omitted and only the differences will be described in more detail.

Referring to FIG. 23, a substrate 110 is provided. In more detail, the substrate 110 includes a first region R1 and a second region R2 disposed at the edge portion of the first region R1. The second region R2 may be provided to the circumference of the first region R1 in operation S31. A buffer dielectric layer 121 is provided on the substrate 110. The buffer dielectric layer 121 may be a silicon oxide layer. A thickness of the buffer dielectric layer 121 may vary depending on an example of a three-dimensional semiconductor device. First material layers 123 and second material layers 125 are alternately stacked on the buffer dielectric layer 121 and then are provided. The lowermost material layer may be the second material layer 125. The second material layers 125 may be formed to allow the upper portion of the second material layers to have a higher wet etch rate than the lower portion thereof. For example, a wet etch rate of the second material layers may be increased progressively farther from the substrate 110.

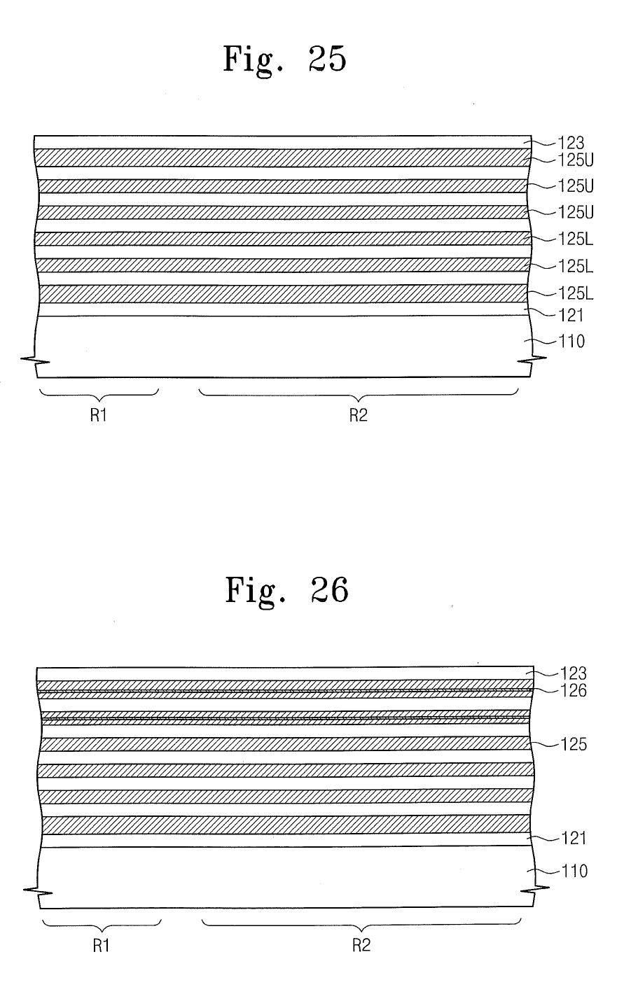

According to one embodiment, referring to FIG. 24, the forming of the second material layers 125 may include forming a lower portion 125L of the second material layers and performing a thermal treatment process on the lower portion 125L. The thermal treatment process may include a rapid thermal process (RTO) and a UV treatment, or a laser treatment. Accordingly, the lower portion 125L of the second material layers may be further densified. Referring to FIG. 25, an upper portion 125U of the second material layers may be formed on the thermally-treated lower portion 125L of the second material layers. In the drawings, it is illustrated that the thermal treatment process is performed once, but the inventive concept is not limited thereto. Moreover, the thermal treatment process is performed on each of the second material layers 125 and the intensity of the thermal treatment is reduced progressively farther from the substrate 110. Because of the above-mentioned thermal treatment, a wet etch rate of the first material layers 123 may be increased as it approaches the upper. The uppermost first insulation layer among the first insulation layers may have a larger wet etch rate than the lowermost first insulation layer.

According to another embodiment, the second material layers 125 may be formed through a CVD method and progressively farther from the substrate, manufacturing process conditions of the second material layers 125 may be changed. For example, the initially-formed second material layers (i.e., the lower portion of the second material layer) are formed densely but the sequentially stacked second material layers may not be formed densely.

According to further another embodiment, referring to FIG. 26, the forming of the second material layers 125 may include inserting a sacrificial layer having a higher wet etch rate than the second material layers into the upper portion of the second material layers. The sacrificial layer 126 may include the same material as the second material layer and may be formed through a CVD method. The sacrificial layer 126 may have a higher wet etch rate since it is less dense than the second material layer 125. A thickness or wet etch rate of the sacrificial layer may be increased as it approaches to the upper. An etch rage of the sacrificial layer 126 may be adjusted by a change of manufacturing conditions of a CVD method.

Referring to FIG. 23 again, a mask pattern 200 is formed on the uppermost first material layer. The mask pattern 200 may be a photoresist pattern, for example. The mask pattern 200 may expose a partial region of the second region R2 in operation S41.

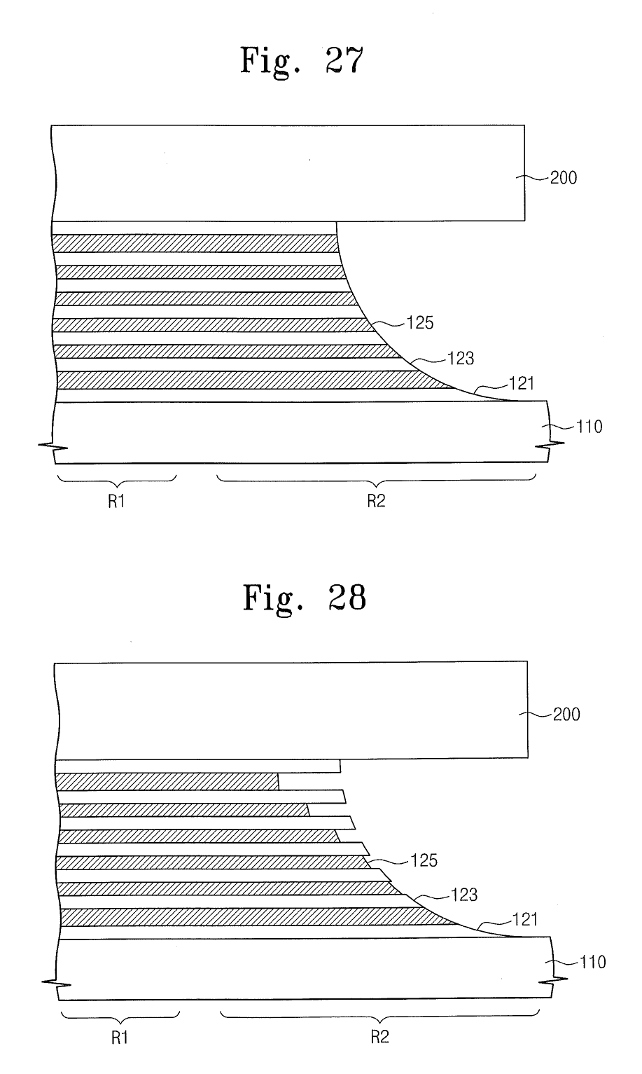

Referring to FIG. 27, the stacked first material layers 123 and second material layers 125 in a region exposed by the mask pattern 200 are isotropically etched through a first etching process in operation S42. The first etching process may be a wet etching process having the same etch rate with respect to the first and second material layers 123 and 125. According to the embodiment described with reference to FIG. 11, a longitudinal line has a very steep slope at the top but a longitudinal line of FIG. 27 may have a gentle slope at the top. This is based on the adjustment of an etch rate of the second material layers 125 described with reference to FIG. 23.

Referring to FIG. 28, the second material layers 125 are isotropically etched through a second etching process in operation S43. The second etching process may include a wet etching process having a higher etch rate with respect to the second material layers 125 than the first material layers 123. In FIGS. 27 and 28, it is described that the order of the first etching process and the second etching process is sequential. However, the inventive concept is not limited thereto and thus the first and second etching processes may be performed simultaneously. The performing of the first and second etching processes simultaneously may include a wet etching process during which the first material layers 123 are removed simultaneously although an etch rate is higher with respect to the second material layers 125 than the first material layers 123.

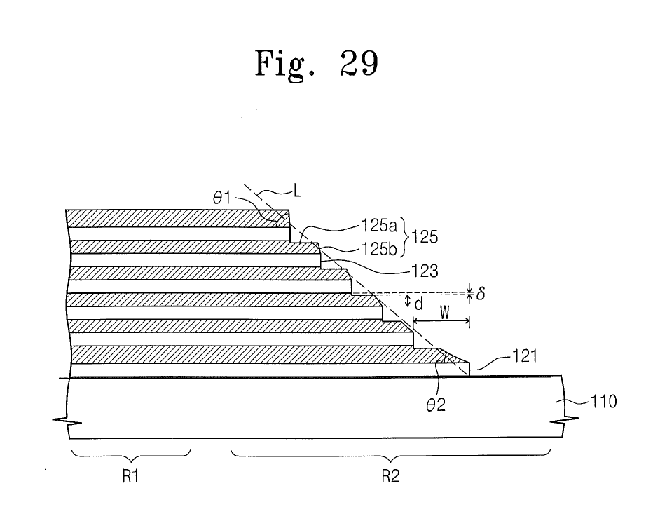

Referring to FIG. 29, the first material layers 123 may be anisotropically etched using the etched second material layers 125 as a mask through a third etching process. The third etching process may include an etch back process in operation S44. Accordingly, the first material layers 123 are interposed, are spaced from each other, and are vertically stacked on the substrate 110. In the second region R2, the second material layers 125 may be formed, where a lower portion protrudes to the side more compared to an upper portion so that the top surfaces of the lower portion may be exposed by the upper portion.

Like one embodiment described with reference to FIG. 13, the second material layers 125 may have a stacked pattern of a stepped shape where their top surfaces 125a and sides 125b are exposed. However, the virtual line L connecting the sides 125b of the second material layers 125 may be further close to a line, compared to the one embodiment. Compared to one embodiment, the width W of the exposed top surface of the second material layers may be further uniform and broader.

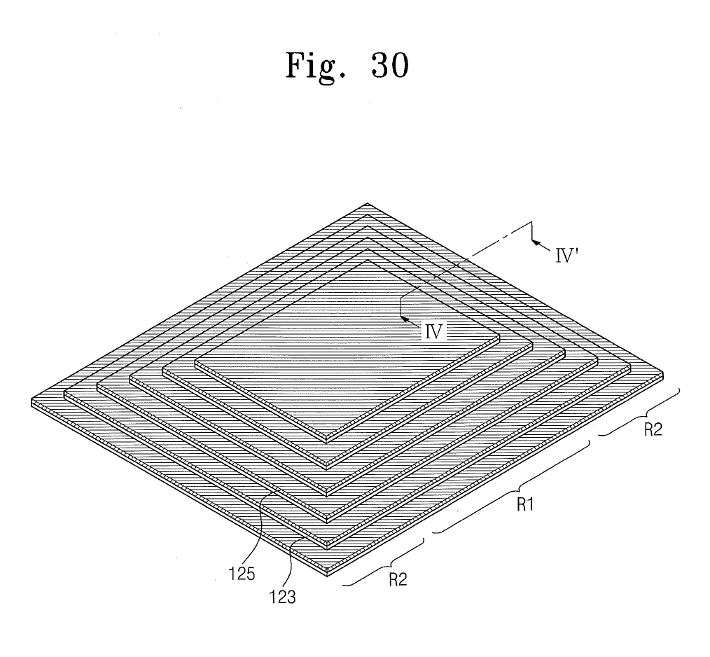

FIG. 30 is a perspective view illustrating a stacked pattern of a stepped shape formed with reference to FIGS. 10 through 29. FIGS. 10 through 29 are sectional views corresponding to the line IV-IV′ of FIG. 30. According to embodiments, the widths of exposed top surfaces of the second material layers may vary.

According to the inventive concept, conductive patterns in the second region R2 of three-dimensional semiconductor devices may have a stepped structure like the second material layers described with reference to FIGS. 13, 17, 22, and 29.

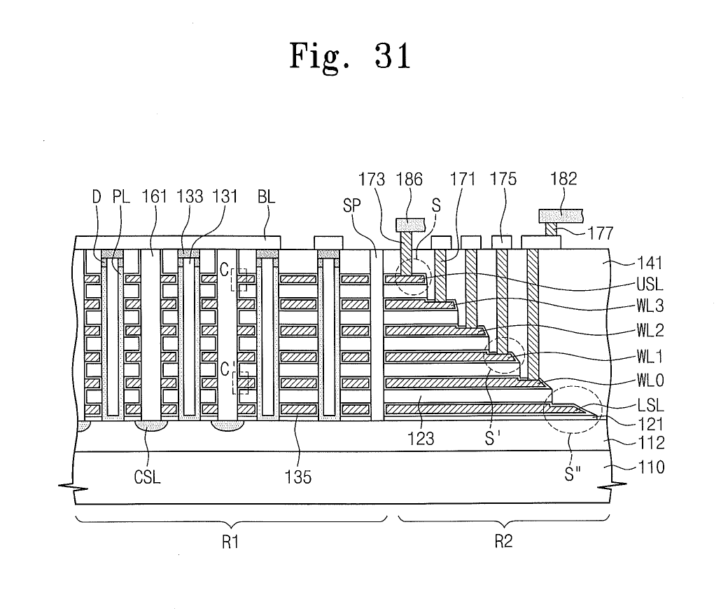

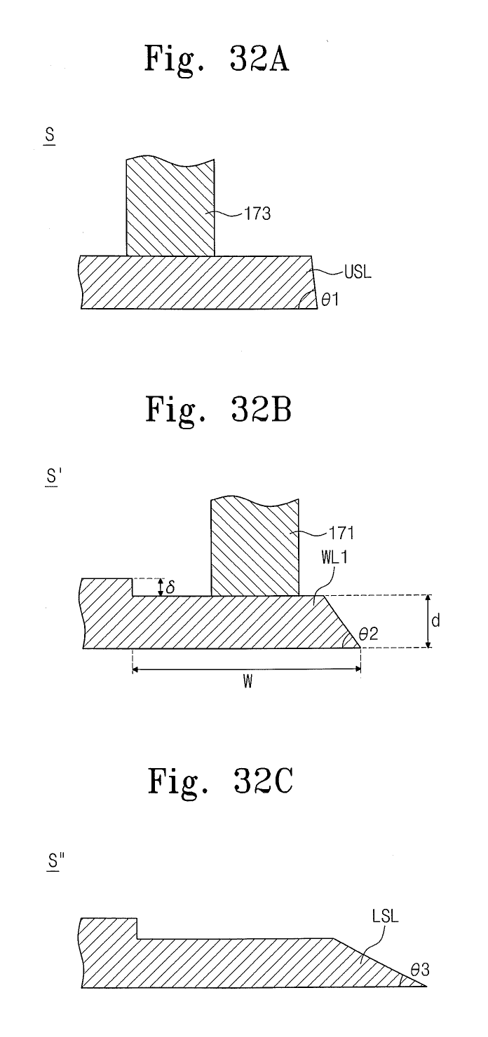

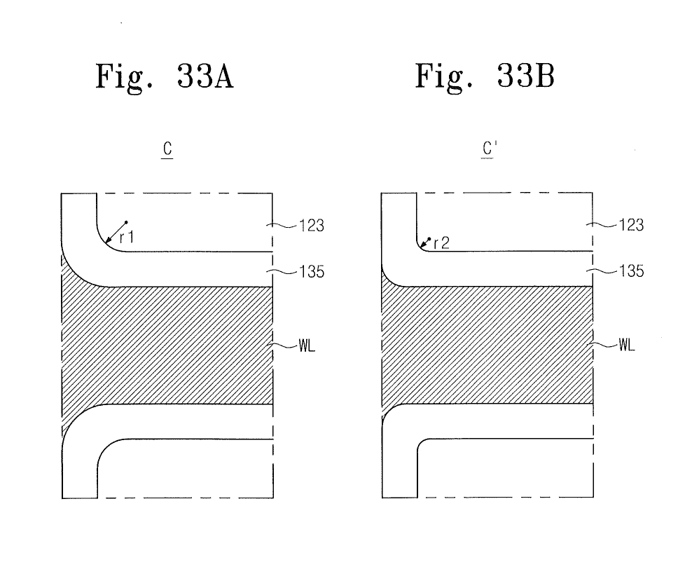

For example, referring to FIGS. 31 and 33, a stepped structure of the three-dimensional semiconductor device 101 may be formed as described with reference to FIG. 29. The conductive patterns LSL, WL0 to WL3, and USL may have a stacked pattern of a stepped shape where their top surfaces and sides are exposed. Forms obtained by the top surface 125a and the side 125b of each of the conductive patterns LSL, WL1 to WL3, and USL may vary based on the height.

Referring to FIGS. 31, 32A, 32B, and 32C, the side of the conductive pattern (i.e., the upper selection line USL of the uppermost conductive pattern) farthest from the substrate may have a greater gradient than that of the conductive pattern (i.e., the lower selection line LSL of the lowermost conductive pattern) closest to the substrate (θ₁>θ₃). The gradients of the sides of the word lines WL0 to WL3 may be between the uppermost conductive pattern θ₁ and the lowermost conductive pattern θ₃ (θ₁>θ₂>θ₃)

The thickness d in the second region R2 of the conductive pattern may be thinner than that in the first region R1. A thickness of the lower second material layers except the uppermost second material layer in the second region R2 may be thinner by predetermined values δ than that in the first region R1. The predetermined values δ of the lower conductive patterns may be the same. It is understood that the sameness of the predetermined values δ may mean that it is in a tolerance range of the anisotropic etching process.

Furthermore, in the embodiment described with reference to FIGS. 23 through 29, the upper portion 125U of the second material layers may have a higher wet etch rate than the lower portion 125L of the second material layer. Due to this, according to the removal process (refer to FIGS. 7E and 8E) of the second material layers 125 in the three-dimensional semiconductor devices 101 and 102, the first material layers 123 adjacent to the upper portion may be exposed longer to a wet etching solution than the first material layers 123 adjacent to the lower portion. In the first region R1, edge shapes of the first material layers 123 adjacent to the insulation separation pattern 161 may vary in the upper portion C and the lower portion C′. Referring to FIG. 33, the radius of curvature r1 of the edge of the first material layers 123 in the portion C of FIG. 31 may be greater than that r2 in the portion C′.

The inner walls of the interlayer insulation layer 141 facing the side of the conductive patterns may vary based on the height. For example, the inner wall of the interlayer insulation layer 141 facing the side of the uppermost conductive pattern among the conductive patterns may have a greater gradient than that facing the side of the lowermost conductive pattern.

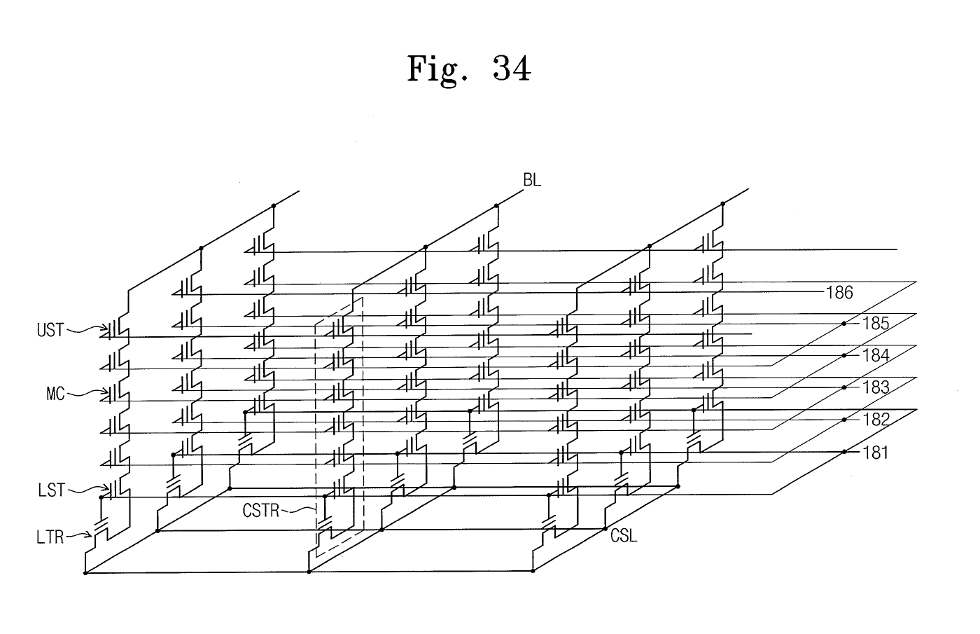

A circuit diagram illustrating a three-dimensional semiconductor device according to embodiments of the inventive concept described with reference to FIG. 3 may be modified diversely. FIG. 34 is a circuit diagram illustrating one modification of the memory block described with reference to FIGS. 1 and 2. Detailed description of overlapping technical features of the circuit diagram described with reference to FIG. 3 will be omitted and only the differences will be described in more detail. Referring to FIG. 34, the three-dimensional semiconductor device according to embodiments of the inventive concept may additionally include a lateral transistor LTR at one end of the cell string CSTR. The lateral transistor LTR is provided between the lower selection transistor LST and the common source line CSL. A gate of the lateral transistor LTR and a gate of the lower selection transistor LST are connected to the lower selection line LSL.

Referring to FIGS. 4B and 4C again, the buffer dielectric layer 121 may be sufficiently thin to serve as a gate insulation layer of a transistor. Once voltage is applied to the lower selection line LSL, a first channel vertical to the substrate 110 is formed in a region corresponding to the lower selection line LSL of the active pillar PL. Simultaneously, a second channel parallel to the substrate 110 is formed in a region of the well 112 adjacent to the lower selection line LSL. The first channel corresponds to a channel of the lower selection transistor LST, and the second channel corresponds to a channel of the lateral transistor LTR.

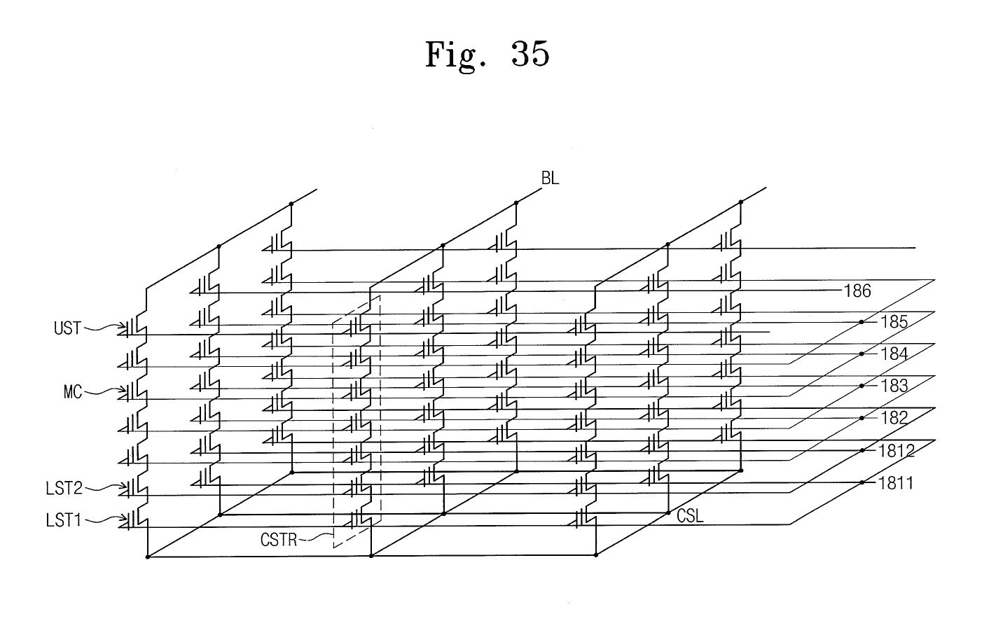

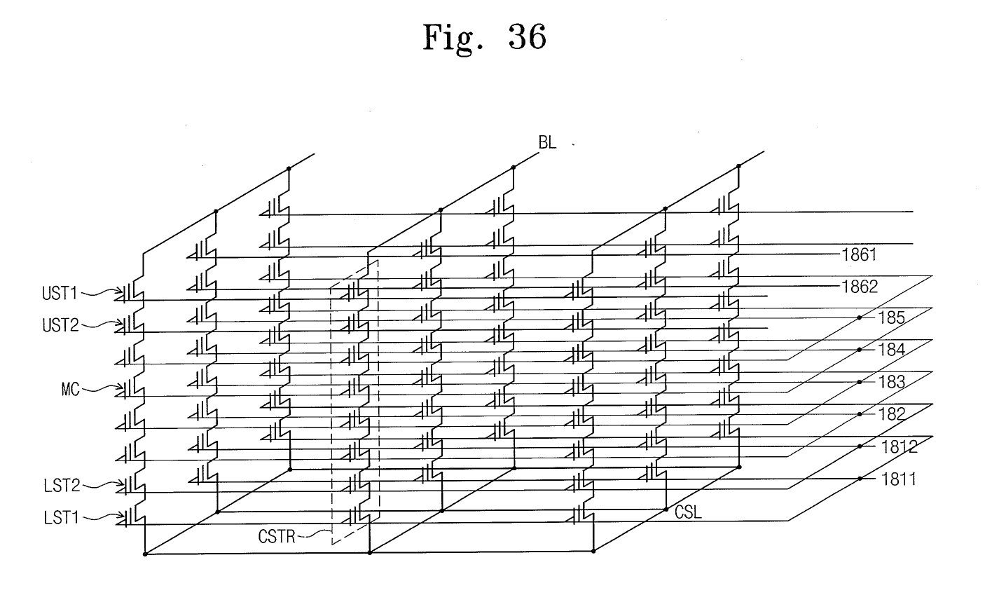

FIG. 35 is a circuit diagram illustrating one modification of the memory block described with reference to FIGS. 1 and 2. Detailed description of overlapping technical features of the circuit diagram described with reference to FIG. 3 will be omitted and only the differences will be described in more detail. Referring to FIG. 35, two lower selection transistors LST1 and LST2 may be provided between the memory cells MC and the common source line CSL. The lower selection transistors LST1 and LST2 of the same height may be commonly connected to the corresponding lower selection lines LSL1 and LSL2.

FIG. 36 is a circuit diagram illustrating one modification of the memory block described with reference to FIGS. 1 and 2. Detailed description of overlapping technical features of the circuit diagram described with reference to FIG. 3 will be omitted and only the differences will be described in more detail. Referring to FIG. 36, two upper selection transistors UST1 and UST2 may be provided between the memory cells MC and the bit lines BL. Gates of the upper selection transistors UST1 and UST2 may be connected to the upper selection lines USL1 and USL2. Furthermore, two lower selection transistors LST1 and LST2 may be provided between the memory cells MC and the common source line CSL. The lower selection transistors LST1 and LST2 of the same height may be commonly connected to the corresponding lower selection lines LSL1 and LSL2.

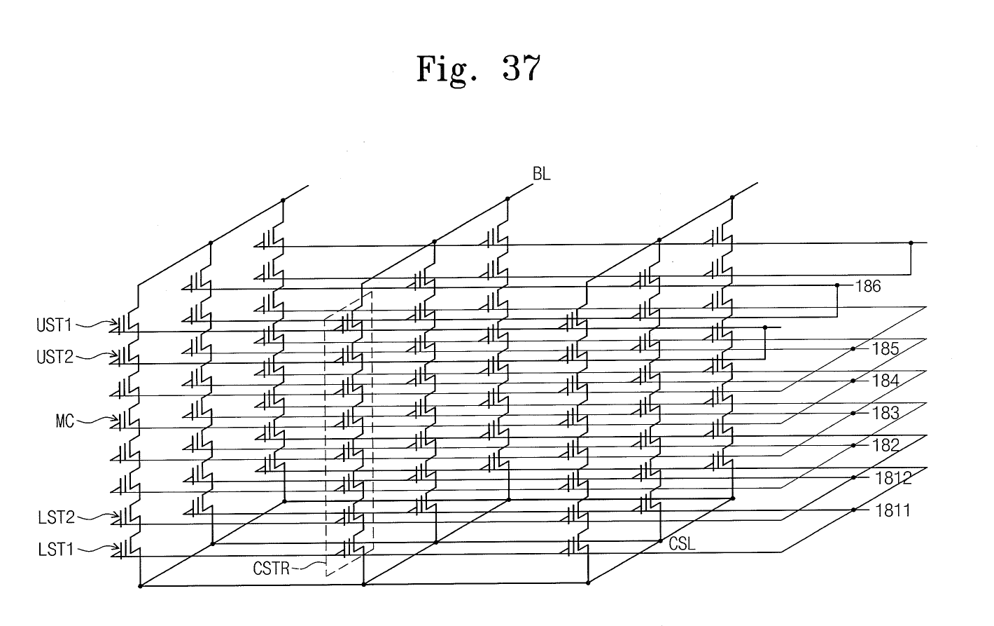

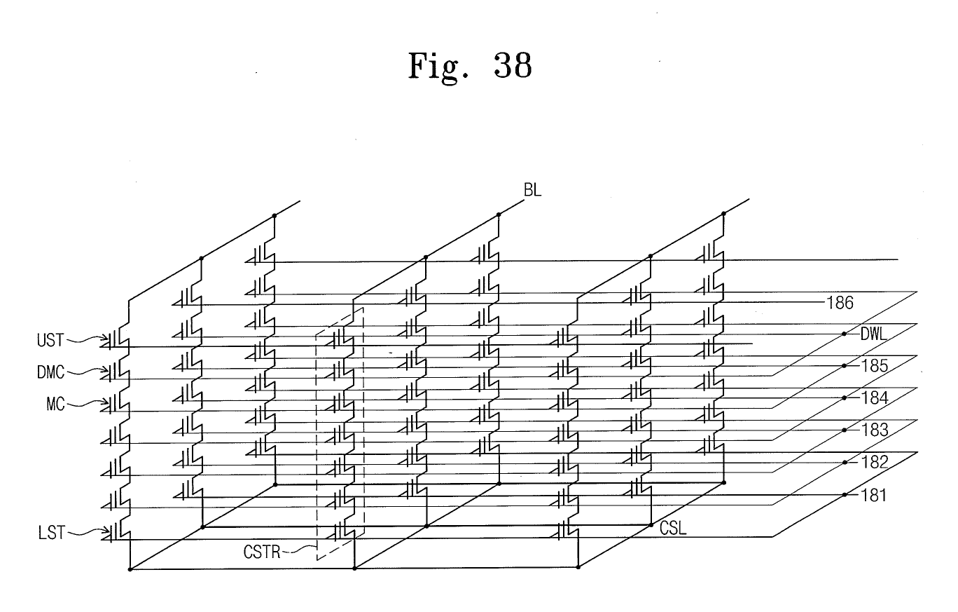

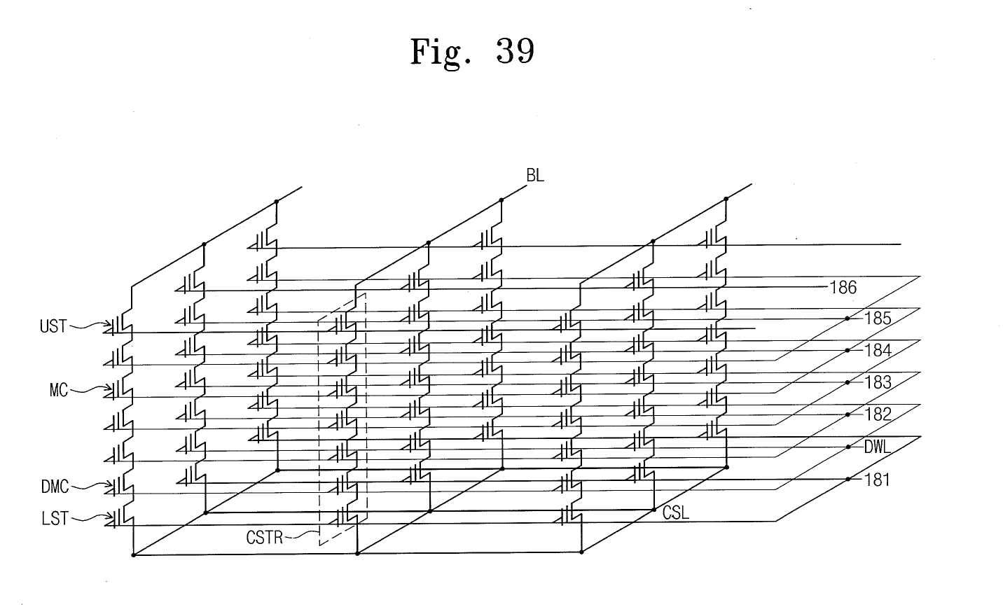

FIG. 37 is a circuit diagram illustrating one modification of the memory block described with reference to FIGS. 1 and 2. Detailed description of overlapping technical features of the circuit diagram described with reference to FIG. 36 will be omitted and only the differences will be described in more detail. Corresponding upper selection lines USL1 and USL2 are commonly connected to the same cell string CSTR.

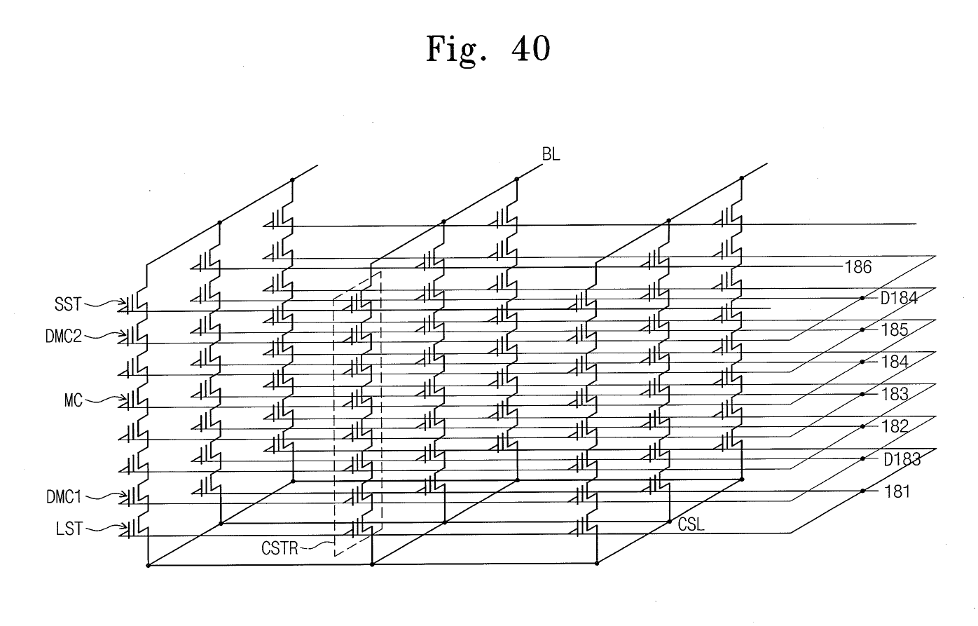

FIG. 38 is a circuit diagram illustrating one modification of the memory block described with reference to FIGS. 1 and 2. Detailed description of overlapping technical features of the circuit diagram described with reference to FIG. 3 will be omitted and only the differences will be described in more detail. A dummy memory cell DMC is provided between the upper selection transistor UST and the memory cells MC in each NAND string. The dummy memory cell DMC is commonly connected to a dummy word line DGL. That is, the dummy word line DGL is provided between the upper selection line USL and the word lines WL0 to WL3.

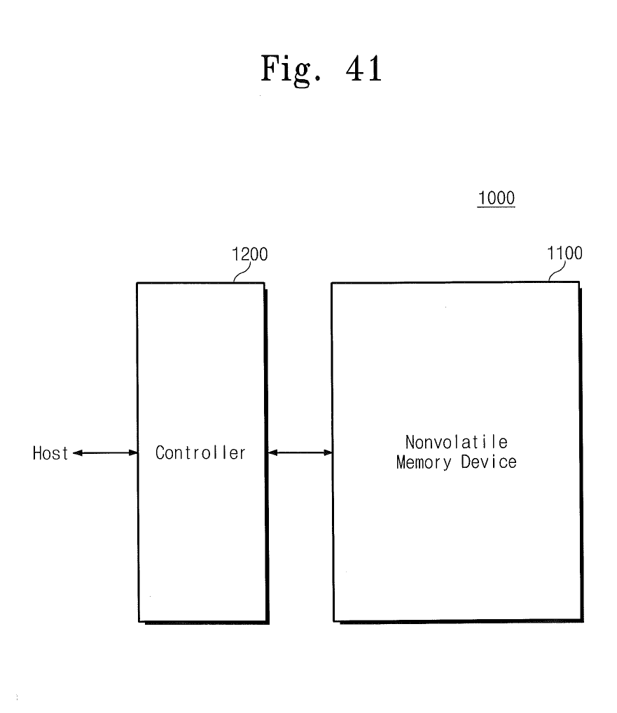

FIG. 39 is a circuit diagram illustrating one modification of the memory block described with reference to FIGS. 1 and 2. Detailed description of overlapping technical features of the circuit diagram described with reference to FIG. 3 will be omitted and only the differences will be described in more detail. A dummy memory cell DMC is provided between the lower selection transistor LST and the memory cells MC in each NAND string. The dummy memory cell DMC is commonly connected to a dummy word line DGL. That is, the dummy word line DGL is provided between the lower selection line LSL and the word lines WL0 to WL3.

FIG. 40 is a circuit diagram illustrating one modification of the memory block described with reference to FIGS. 1 and 2. Detailed description of overlapping technical features of the circuit diagram described with reference to FIG. 3 will be omitted and only the differences will be described in more detail. A lower dummy memory cell DMC11 is provided between the lower selection transistor UST and the memory cells MC in each NAND string. The lower dummy memory cell DMC1 is commonly connected to the lower dummy word line DGL1. That is, the lower dummy word line DGL1 is provided between the lower selection line LSL and the word lines WL0 to WL3. An upper dummy memory cell DMC2 is provided between the upper selection transistor UST and the memory cells MC in each NAND string. The upper dummy memory cell DMC2 is commonly connected to an upper dummy word line DGL2. That is, the upper dummy word line DGL2 is provided between the upper selection line USL and the word lines WL0 to WL3.

Structures of the three-dimensional semiconductor devices 101, 102, and 103 may be modified to correspond to the circuit diagram of the memory block described with reference to FIGS. 34 through 40.

In the above embodiments, it is shown that four gates are used but the inventive concept is not limited thereto. Moreover, structures in the first region of the three-dimensional semiconductor devices described in the above embodiments are just examples of the inventive concept and thus may be diversely modified. The inventive concept is not limited thereto.

In the above embodiments, it is exemplarily described that the first region includes a memory cell but the inventive concept is not limited thereto. Thus, the first region may be a logic region including logic devices. That is, a second region for delivering an electric signal to wirings of logic devices that are stacked vertically on a substrate may be realized like the above-mentioned embodiments.

FIG. 41 is a block diagram illustrating a memory system 1000 including the above-mentioned three-dimensional semiconductor device. Referring to FIG. 41, the memory system 1000 includes the nonvolatile memory device 1100 and a controller 1200. The nonvolatile memory device 1100 and/or the controller 1200 may be realized with the above-mentioned three-dimensional semiconductor device. The nonvolatile memory device 1100 may be configured as described with reference to FIGS. 1 through 40. The controller 1200 is connected to a host and the nonvolatile memory device 1100. The controller 1200 is configured to access the nonvolatile memory device 1100 in response to a request from the host. For example, the controller 1200 is configured to control read, write, erase, and background operations of the nonvolatile memory device 1100. The controller 1200 is configured to provide an interface between the nonvolatile memory device 1100 and the host. The controller 1200 is configured to drive a firmware for controlling the memory device 1200.

For example, as described with reference to FIG. 1, the controller may be configured to provide a control signal CTRL and an address ADDR to the nonvolatile memory device 1100. The controller 1200 is configured to exchange data with the nonvolatile memory device 1200. Exemplarily, the controller 1200 may further include components such as Random Access Memory (RAM), a processing unit, a host interface, and a memory interface. The RAM may be used as at least one of a cache memory between the nonvolatile memory device 1100 and the host and a buffer memory between the nonvolatile memory device 1100 and the host. The processing unit may control general operations of the controller 1200. The host interface includes a protocol for performing data exchange between the host and the controller 1200. For example, the controller 1200 may be configured to communicate with an external (e.g., a host) through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol. The memory interface interfaces with the semiconductor device 1100. For example, the memory interface includes a NAND interface or a NOR interface.

The memory system 1000 may be configured to include an error correction block additionally. The error correction block is configured to detect and correct an error of data read from the nonvolatile memory device 1100 using an Error Correction Code (ECC). For example, the error correction block may be provided as a component of the controller 1200. The error correction block may be provided as a component of the nonvolatile memory device 1100.

The controller 1200 and the nonvolatile memory device 1100 may be integrated into one semiconductor device. For example, the controller 1200 and the nonvolatile memory device 1100 may be integrated into one semiconductor device, thereby constituting a memory card. For example, the controller 1200 and the nonvolatile memory device 1100 are integrated into one semiconductor device, thereby constituting a memory card including one of PC cards such as Personal Computer Memory Card International Association (PCMCIA), compact flash cards such as CF, smart media cards such as SM and SMC, memory sticks, multimedia cards such as MMC, RS-MMC, MMCmiR2o, SD cards such as SD, miniSD, miR2oSD, and SDHC, and universal flash memory devices such as UFS.

The controller 1200 and the nonvolatile memory device 1100 may be integrated into one semiconductor device, thereby constituting a Solid State Drive (SSD). The SSD may include a storage device configured to store data in a semiconductor memory. When the memory system 1000 is used as the SSD, an operating speed of the host connected to the memory system 1000 is drastically improved.

As another embodiment, the memory system 1000 may be provided as one of various components of an electronic device such as a computer, a ultra mobile personal computer (UMPC), a workstation, a net-book, a personal digital assistance (PDA), a portable computer (PC), a web tablet, a wireless phone, a mobile phone, a smart phone, an e-book, a portable multimedia player (PMP), a portable game console, a navigation, a black box, a digital camera, a digital multimedia broadcasting (DMB) player, a digital audio recorder, a digital audio player, a digital picture recorder, a digital picture player, a digital video recorder, a digital video player, a device for transmitting and receiving information under wireless environment, one of various electronic devices constituting a home network, one of various electronic devices constituting a computer network, one of various electronic devices constituting a telematics network, a radio frequency identification (RFID) device, and one of various components constituting a computing system.

For example, the nonvolatile memory device 1100 or the memory system 1000 may be mounted through various kinds of packages. For example, the nonvolatile memory device 1100 or the memory system 1000 may be packaged and mounted through package methods such as Package on Package (PoP), Ball Grid Arrays (BGA), Chip Scale Packages (CSP), Plastic Leaded Chip Carrier (PLCC), Plastic Dual In-line Package (PDIP), Die in Waffle Pack, Die in Wafer Form, Chip On Board (COB), Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), and Wafer-level Processed Stack Package (WSP).

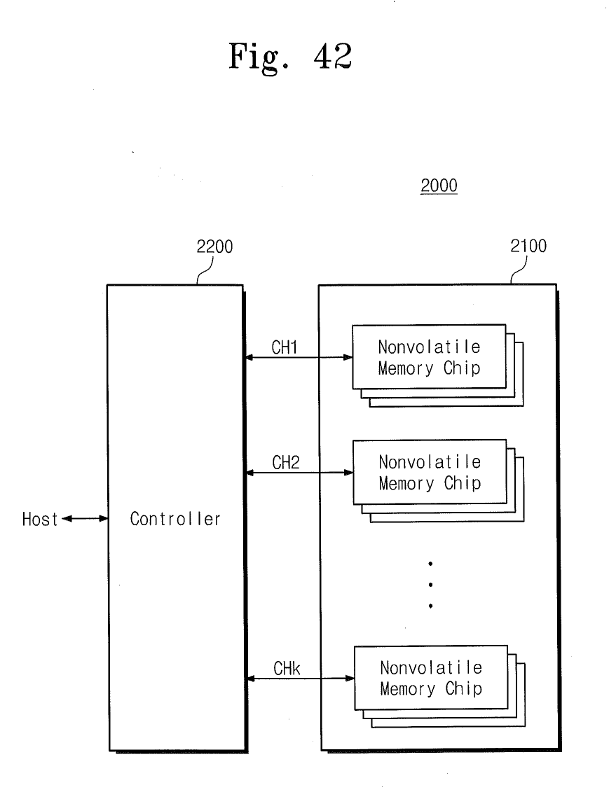

FIG. 42 is a block diagram illustrating an application example of the memory system 1000 of FIG. 41. Referring to FIG. 42, a memory system 2000 includes a nonvolatile memory device 2100 and a controller 2200. The nonvolatile memory device 2100 may include a plurality of nonvolatile memory chips. The plurality of nonvolatile memory chips may be divided into a plurality of groups. Each group of the nonvolatile memory chips may be configured to communicate with the controller 2200 through one common channel. In FIG. 42, it is described that the plurality of nonvolatile memory chips communicate with the controller 2200 through first to k channels CH1 to CHk. Each nonvolatile memory chip may be realized with the three-dimensional semiconductor device described with reference to FIGS. 1 through 39. In FIG. 42, it is described that the plurality of nonvolatile memory chips are connected to one channel. However, it is apparent that the memory system 2000 may be modified to allow one nonvolatile memory chip to connect to one channel.

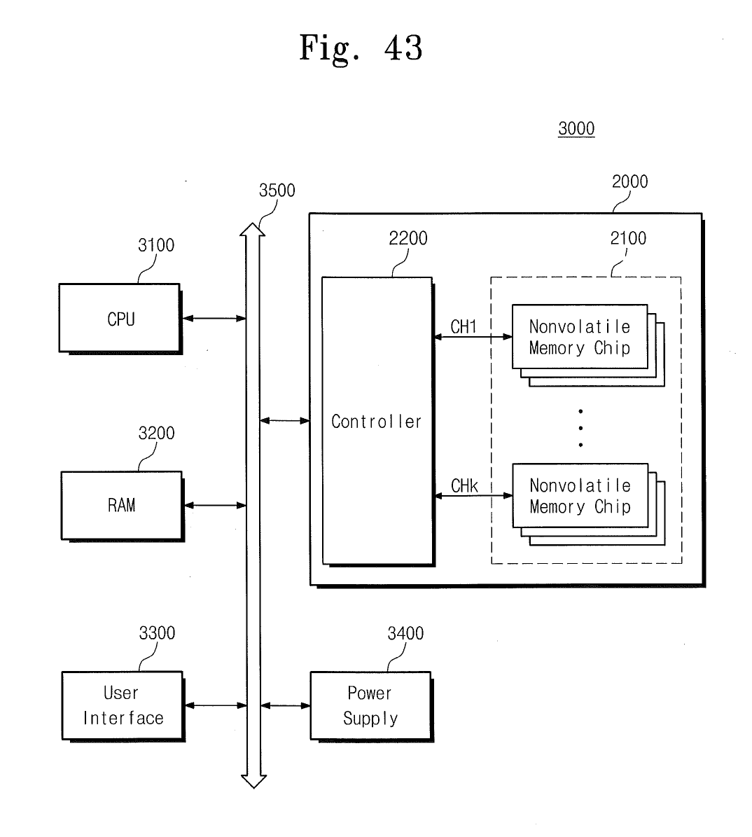

FIG. 43 is a block diagram illustrating a computing system 3000 including the memory system 2000 described with reference to FIG. 42. Referring to FIG. 43, the computing system 3000 includes a central processing unit (CPU) 3100, a RAM 3200, a user interface 3300, a power supply 3400, and the memory system 2000. The memory system 3500 is electrically connected to the CPU 3100, the RAM 3200, the user interface 3300, and the power supply 3400 through a system bus 3500. Data provided through the user interface 3300 or processed by the CPU 3100 are stored in the memory system 2000.

In FIG. 43, it is described that the nonvolatile memory device 2100 is connected to the system bus 3500. However, the nonvolatile memory device 2100 may be configured to directly connect to the system bus 3500. In FIG. 43, the memory system 2000 described with reference to FIG. 42 is provided. However, the memory system 2000 may be replaced with the memory system 1000 described with reference to FIG. 41. For example, the computing system 3000 may be configured to include the memory systems 1000 and 2000 described with reference to FIGS. 41 and 42.

According to inventive concept of the inventive concept, in a second region at the edge of a first region, a stepped structure of a plurality of conductive patterns stacked on a substrate may be easily formed. Through one-time photo process and at least one-time wet etching process for exposing the second region, a plurality of conductive patterns may have a stepped structure with reasonable costs. A plurality of photo and etching processes are not required to form a conductive pattern of the stepped structure.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

1. A method of forming a nonvolatile memory device, comprising:
forming a stack of layers of different materials on a substrate, said stack of layers comprising a plurality of first layers of a first material and a plurality of second layers of a second material arranged in an alternating sequence of first and second layers;
isotropically etching a first portion of the stack of layers for a sufficient duration to define a first trench therein that exposes sidewalls of the alternating sequence of first and second layers;
recessing sidewalls of each of the plurality of first layers relative to sidewalls of adjacent ones of the plurality of second layers; and then
recessing sidewalls of the plurality of second layers to thereby expose portions of upper surfaces of the plurality of first layers.

2. The method of claim 1, wherein the exposed portions of the upper surfaces of the plurality of first layers are displaced laterally relative to each other.

3. The method of claim 1, wherein the plurality of first layers comprise an electrically conductive material; and wherein the plurality of second layers comprise an electrically insulating material.

4. The method of claim 1, wherein the plurality of first layers comprise polycrystalline silicon; and wherein said recessing sidewalls of the plurality of second layers is followed by selectively etching the plurality of first layers in sequence to define a plurality of side-by-side stacks of word lines of the memory device.

5. The method of claim 1, further comprising forming conductive pillars on the exposed portions of the upper surfaces of the plurality of first layers.

6. A method of forming a nonvolatile memory device, comprising:
forming a stack of layers of different materials on a substrate, said stack of layers comprising a plurality of first layers of a first material and a plurality of second layers of a second material arranged in an alternating sequence of first and second layers;
isotropically etching a first portion of the stack of layers for a sufficient duration to define a first trench therein that exposes sidewalls of the alternating sequence of first and second layers;
recessing sidewalls of each of the plurality of first layers exposed by the trench relative to sidewalls of adjacent ones of the plurality of second layers by selectively etching the first material at a faster rate than the second material; then
isotropically etching the first portion of the stack of layers for a sufficient duration to deepen the first trench; and then
recessing sidewalls of the plurality of second layers relative to sidewalls of the plurality of first layers to thereby expose portions of upper surfaces of the plurality of first layers.

7. The method of claim 6, wherein said isotropically etching the first portion of the stack of layers for a sufficient duration to deepen the first trench comprises isotropically etching the first portion of the stack of layers for a sufficient duration to expose the substrate.

8. A method of forming a semiconductor device, the method comprising:
providing a substrate including a first region and a second region adjacent to the first region;
forming first material layers and second material layers to be alternately stacked on the substrate, wherein the first material layers and the second material layers are different to each other;
forming a mask pattern exposing a partial region of the second region on an uppermost material layer; and
forming a step-shaped stacked pattern comprising top surfaces and sides of the exposed second material layers, by wet etching the stacked first material layers and second material layers in the partial region exposed by the mask pattern.

9. The method of claim 8, wherein the wet etching comprises:
performing a first wet etching process having the same etch rate with respect to the first material layers and the second material layers; and
performing a second wet etching process having a higher etch rate with respect to the second material layers than the first material layers.

10. The method of claim 8, further comprising anisotropically etching the first material layers using the wet etched second material layers as a mask.

11. The method of claim 8, wherein the wet etching comprises performing a first etching process having a higher etch rate with respect to the second material layers than the first material layers.

12. The method of claim 11, wherein
the first wet etching process is performed not to expose the substrate; and
the wet etching further comprises, after the first wet etching process, exposing the substrate by performing a second wet etching process having a smaller etch rate difference with respect to the first material layers and the second material layers than the first wet etching process.

13. The method of claim 8, wherein the second material layers comprise lower second material layers and upper second material layers, the upper second material layers having a higher wet etch rate than the lower second material layers.

14-22. (canceled)
